(19) United States
(12) Patent Application Publication
(10) Pub. No.: US 2026/0215182 A1
(43) Pub. Date: Jul. 23, 2026

(54) LOW K DIELECTRIC GAPFILL

(71) Applicant: Lam Research Corporation, Fremont, CA (US)

(72) Inventors: Bart J. van Schravendijk, Palo Alto, CA (US); Michael David Galluzzo, Portland, OR (US); Joel David Smith, Tualatin, OR (US); Dennis M. Hausmann, Lake Oswego, OR (US)

(21) Appl. No.: 19/139,049

(22) PCT Filed: Dec. 14, 2023
(86) PCT No.: PCT/US2023/084005

§ 371 Date: Jun. 13, 2025

Related U.S. Application Data
(60) Provisional application No. 63/387,605, filed on Dec. 15, 2022.

(51) Int. Cl. H10P 14/692; H10P 14/60; H10W 20/00

(52) U.S. Cl. CPC H10P 14/6927; H10P 14/6339; H10P 14/6522; H10W 20/098

(57) ABSTRACT

The present invention involves a method for depositing low-k dielectric material in a feature, the method comprising: depositing a silicon-containing layer in one or more recessed features of a substrate; exposing at least a portion of the silicon-containing layer to an oxygen-containing species, thereby forming a silicon oxide-containing portion in the silicon-containing layer; and at least partially etching the silicon oxide-containing portion.

### INCORPORATION BY REFERENCE

A PCT Request Form is filed concurrently with this application as part of the present application. Each application that the present application claims benefit of or priority to as identified in the concurrently filed PCT Request Form is incorporated by reference herein in their entireties and for all purposes.

### BACKGROUND

During a semiconductor device fabrication process, a dielectric material may be formed to fill the gaps between metal features. As the node size decreases, the size of a gap between the metal features also decreases. Controlled gap filling may be particularly challenging for high aspect ratio features.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method, the method including: depositing a silicon-containing layer in one or more recessed features of a substrate; exposing at least a portion of the silicon-containing layer to an oxygen-containing species, thereby forming a silicon oxide-containing portion in the silicon-containing layer; and at least partially etching the silicon oxide-containing portion.

In some embodiments, depositing the silicon-containing layer includes introducing a silicon-containing precursor to adsorb and thermally decompose on surfaces of the substrate to form the silicon-containing layer.

In some embodiments, the silicon-containing layer includes silicon carbide, silicon oxycarbide, hydrogenated silicon oxycarbide, or silicon oxycarbonitride.

In some embodiments, the silicon-containing layer includes a conformal layer.

In some embodiments, the silicon-containing layer includes a pinched off layer.

In some embodiments, the oxygen-containing species diffuses into the silicon-containing layer to a penetration depth.

In some embodiments, the oxygen-containing species includes oxygen, ozone, hydrogen peroxide, oxygen-containing radicals, plasmas thereof, or mixtures thereof.

In some embodiments, exposing the at least the portion of the silicon-containing layer includes converting the portion of the silicon-containing layer to the silicon oxide-containing portion.

In some embodiments, the at least the portion of the silicon-containing layer is exposed to the oxygen-containing species at pressure of about 0.5 to about 5 Torr.

In some embodiments, the at least the portion of the silicon-containing layer is exposed to the oxygen-containing species at pressure of about 1 to about 20 Torr.

In some embodiments, the portion of the silicon oxide-containing portion is etched by exposing the silicon oxide-containing portion to hydrogen fluoride.

In some embodiments, depositing, exposing, and at least partially etching are performed without breaking vacuum.

In some embodiments, the method further includes repeating deposition, exposure, and etch operations to partially fill or completely fill the one or more recessed features of the substrate with a silicon-containing gapfill material.

In some embodiments, the one or more recessed features have an aspect ratio of about 2:1 to about 6:1.

Another aspect involves a method, the method including: conformally depositing a doped or undoped silicon carbide layer in one or more recessed features on a substrate; converting at least a portion of the doped or undoped silicon carbide layer to a silicon oxide; and at least partially etching the silicon oxide.

In some embodiments, conformally depositing the doped or undoped silicon carbide layer includes introducing a silicon-containing precursor to adsorb and thermally decompose on surfaces of the substrate and generating a plasma to form the doped or undoped silicon carbide layer.

In some embodiments, converting the at least the portion of the doped or undoped silicon carbide layer to the silicon oxide includes introducing an oxygen-containing species into the one or more recesses.

In some embodiments, converting the at least the portion of the doped or undoped silicon carbide layer to the silicon oxide includes removing carbon from the doped or undoped silicon carbide layer.

In some embodiments, the doped or undoped silicon carbide layer is converted to the silicon oxide at a pressure of about 0.5 to about 5 Torr.

In some embodiments, the at least the portion of the silicon containing layer is exposed to the oxygen containing species at a pressure of about 1 to about 20 Torr.

In some embodiments, the doped or undoped silicon carbide layer includes silicon carbide, silicon oxycarbide, hydrogenated silicon oxycarbide, or silicon oxycarbonitride.

In some embodiments, the doped or undoped silicon carbide layer is deposited by chemical vapor deposition or plasma enhanced chemical vapor deposition.

In some embodiments, the oxygen-containing species includes oxygen, ozone, hydrogen peroxide, oxygen-containing radicals, plasmas thereof, or mixtures thereof.

In some embodiments, the silicon oxide is etched by exposing the portion of the silicon oxide to hydrogen fluoride.

In some embodiments, the doped or undoped silicon carbide layer is converted to the silicon oxide at a pressure about 1 to about 20 Torr.

In some embodiments, the doped silicon carbide layer includes one or more dopants including oxygen, nitrogen, or a mixture thereof.

In some embodiments, the method further includes repeating conformal the depositing, the converting, and at least partially the etching to partially fill or completely fill the one or more recessed features of the substrate with a silicon-containing gapfill material.

In some embodiments, wherein the one or more recessed features have an aspect ratio of about 2:1 to about 6:1.

Another aspect involves an apparatus, the apparatus including: one or more process chambers, each process chamber including a chuck; one or more gas inlets into the process chambers and associated reactant delivery system; and a controller having at least one processor and a memory, whereby the at least one processor and the memory are communicatively connected with one another, the at least one processor is at least operatively connected with the reactant delivery system, and the memory stores computer-executable instructions for controlling the at least one processor for: causing a substrate to be provided to one of the one or more process chambers, causing introduction of a silicon-containing precursor to the one or more process chambers; causing one or more oxygen-containing species to be introduced into the one or more process chambers, causing the substrate to be exposed to the oxygen-containing species; and causing the substrate to be exposed to an etch chemistry.

Another aspect involves an apparatus, the apparatus including: one or more process chambers, each process chamber including a chuck; one or more gas inlets into the process chambers and associated reactant delivery system; one or more remote plasma sources fluidly connected with the one or more process chambers, one or more gas inlets, and the associated reactant delivery system; and a controller having at least one processor and a memory, whereby the at least one processor and the memory are communicatively connected with one another, the at least one processor is at least operatively connected with the reactant delivery system, and the memory stores computer-executable instructions for controlling the at least one processor for: causing a substrate to be provided to one of the one or more process chambers, causing introduction of a silicon-containing precursor to the one or more process chambers; causing one or more oxygen-containing radicals to be introduced from the one or more remote plasma sources into the one or more process chambers; causing the substrate to be exposed to the oxygen containing radicals at a pressure of about 1 to about 20 Torr; and causing the substrate to be exposed to an etch chemistry.

As used herein, the term “about” means+/−10% of any recited value. As used herein, this term modifies any recited value, range of values, or endpoints of one or more ranges.

These and other aspects are described further below with reference to the drawings.

### BRIEF DESCRIPTION OF THE DRAWINGS

FIG. 1 is a flow chart of an example method of performing deposition, oxidization, and etching of a silicon-containing layer in a feature of a substrate according to some embodiments.

FIGS. 2A-2D are cross-sectional schematic illustrations of a feature of an example substrate undergoing gapfill according to some embodiments.

FIGS. 3A-3D are cross-sectional schematic illustrations of a feature of an example substrate undergoing gapfill according to some embodiments.

FIGS. 4A-4D are cross-sectional schematic illustrations of a feature of an example substrate undergoing gapfill according to some embodiments.

FIG. 5 is a schematic diagram of an example process chamber according to some embodiments.

FIG. 6 is a schematic diagram of an example process tool according to some embodiments.

FIG. 7A is a schematic diagram of an example processing apparatus according to some embodiments.

FIG. 7B is a schematic diagram showing arrangement of light sources for the example processing apparatus in FIG. 7A according to some embodiments.

FIG. 7C is a schematic diagram showing arrangement of light sources for the example processing apparatus in FIG. 7A according to some embodiments.

FIG. 7D is a schematic diagram showing a cross-sectional depiction of a pedestal for the example processing apparatus in FIG. 7A according to some embodiments.

FIG. 7E is a schematic diagram showing a cross-sectional depiction of a pedestal in FIG. 7D with additional features according to some embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### TERMINOLOGY AND DEFINITIONS

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which Lis an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which Lis an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof, or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which Lis C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₂ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₁₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{$5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant ~SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)(—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant-OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₙ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, baloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, 300 mm, or 450 mm. Examples of wafer materials include silicon (Si), gallium arsenide (GaAs), and silicon germanium (SiGe). Besides semiconductor wafers, other workpieces that may take advantage of the disclosed embodiments include various articles such as printed circuit boards, magnetic recording media, magnetic recording sensors, mirrors, optical elements, display devices or components such as backplanes for pixelated display devices, flat-panel displays, micro-mechanical devices and the like. The workpiece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition (PVD), chemical vapor deposition (CVD), atomic layer deposition (ALD), electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

Substrates may include “features” or “trenches.” “Features” as used herein may refer to non-planar structures, typically a surface being processed in a semiconductor device fabrication operation. Examples of features, which may also be referred to as “negative features” or “recessed features,” include trenches, holes, volume, vias, gaps, recessed regions, and the like. These terms may be used interchangeably in the present disclosure. One example of a feature is a hole or via in a semiconductor substrate or in a layer on the substrate. Another example is a trench in a substrate or layer. A feature typically has an aspect ratio (depth to lateral dimension). A feature may be characterized by one or more of narrow and/or re-entrant openings, constrictions within the feature, and high aspect ratios. A feature having a high aspect ratio can have a depth to lateral dimension aspect ratio equal to or greater than about 10:1, equal to or greater than about 15:1, equal to or greater than about 20:1, equal to or greater than about 25:1, equal to or greater than about 30:1, equal to or greater than about 40:1, equal to or greater than about 50:1, or equal to or greater than about 100:1. In various embodiments, the feature may have an under-layer, such as a barrier layer or adhesion layer. Non-limiting examples of under-layers include dielectric layers and conducting layers, e.g., silicon oxides, silicon nitrides, undoped silicon carbides, oxygen-doped silicon carbides, nitrogen-doped silicon carbides, metal oxides, metal nitrides, metal carbides, and metal layers.

Features of a substrate can be of various types. In some embodiments, a feature can have straight sidewalls, positively sloped sidewalls, or negatively sloped sidewalls. In some embodiments, a feature can have sidewall topography or sidewall roughness, which may occur as a result of an etch process to form the feature. In some embodiments, a feature can have a feature opening that is wider at the top of the feature than at the bottom, or a feature can have a feature opening that is wider at the bottom of the feature than at the top.

Manufacture of semiconductor devices typically involves forming one or more silicon-containing layers on a semiconductor substrate in an integrated fabrication process. Silicon-containing layers may include doped or undoped silicon oxide, doped or undoped silicon nitride, or doped or undoped silicon carbide. For example, silicon-containing layer may include silicon oxide, silicon nitride, silicon carbide, silicon oxycarbide, hydrogenated silicon oxycarbide, silicon oxynitride, silicon carbonitride, and a combination thereof. Technology nodes are continually shrinking in the integrated circuit manufacturing industry. With each technology node, device geometries also shrink, and pitch becomes smaller. High aspect ratio gaps in such technology nodes may need to be filled with insulating material, such as insulating material with a low dielectric constant (low-k). Semiconductor integration operations may involve filling high aspect ratio gaps with low-k dielectric materials. Examples include fabrication of shallow trench isolation, inter-metal dielectric layers, passivation layers, and the like. In another example, as device features shrink laterally, unwanted conductive coupling may occur as conductive materials are formed closer and closer, which can lead to parasitic capacitance, delay in signal propagation, and signal crosstalk due to capacitive effects. Low-k materials as the interlayer dielectric (ILD) of conductive interconnects may reduce parasitic capacitance, signal delay, and signal crosstalk. Some applications, including fin field effect transistor (finFET) structures and dynamic random-access memory (DRAM) bit structures, may involve deposition of low-k materials as sidewall spacer materials.

Silicon carbide materials, including doped and undoped silicon carbide materials, may serve as insulating materials in integrated circuit applications that not only have a low dielectric constant, but also have improved step coverage, thermal stability, wet etch resistance, dry etch selectivity to oxide/nitride, and high breakdown voltages. For example, incorporation of oxygen atoms and/or nitrogen atoms may tune the properties of silicon carbide materials. In some embodiments, an oxygen-doped silicon carbide film can serve as an insulating material in integrated circuit applications that provides a low dielectric constant, increased wet etch resistance to thereby survive device integration operations, and increased dry etch selectivity to oxide/nitride.

Forming high-quality doped silicon-containing thin films may have certain challenges, such as providing films with excellent step coverage, low dielectric constants, and/or high breakdown voltages etc. Once a silicon-containing layer is formed with desired properties and compositions, additional challenges may exist to conformally deposit the silicon-containing layer in high aspect ratio features. Conformal deposition may be desirable in gapfill of the high aspect ratio features. Semiconductor fabrication processes often involve gapfill processes of dielectric gapfill processes. Chemical vapor deposition (CVD) or atomic layer deposition (ALD) methods may be used to fill features. Some deposition techniques may result in formation of seams or voids within the feature. In some cases, the presence of seams and/or voids in gapfill may lead to high resistance, contamination, loss of filled material, degraded performance, and even device failure.

### Process Flow

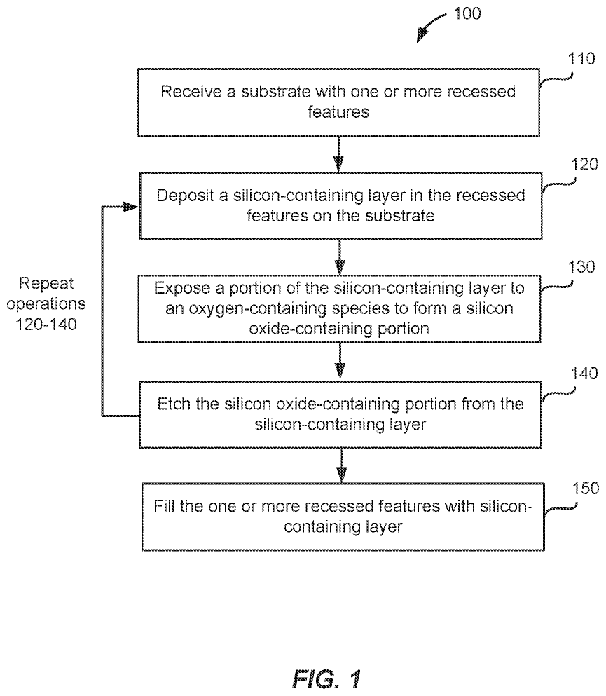

FIG. 1 illustrates a flow chart 100 of an example method of performing deposition, oxidization, and etching of a silicon-containing layer in a feature of a substrate according to some embodiments. In operation 110, a substrate with one or more features may be provided into a process chamber. In some embodiments, the substrate is transported into the process chamber. The feature may be a recessed feature, for example, a trench formed between neighboring metal patterns. The feature may have an aspect ratio of about 2:1 to about 6:1.

In operation 120, a silicon-containing layer may be formed in the recessed features on the substrate. In some embodiments, a silicon-containing layer may be deposited to fill the recessed features. The silicon-containing layer may be a doped or undoped silicon carbide. Doped silicon carbide may include one or more dopants including oxygen, nitrogen, or a mixture thereof. The silicon-containing layer may include silicon carbide (SIC), silicon oxycarbide (SiOC), hydrogenated silicon oxycarbide (SiCOH), or silicon oxycarbonitride (SiOCN). The silicon-containing layer may be deposited by CVD, plasma enhanced CVD (PECVD), ALD (thermal ALD), plasma enhanced ALD (PEALD), or any suitable deposition technique. In some embodiments, the silicon-containing layer may be deposited by PECVD.

A thickness of the silicon-containing layer may depend on various deposition parameters including, not limited to, chamber pressure, chamber temperature, precursor flow rate, deposition time or the like. For example, deposition time may be controlled to achieve a silicon-containing layer having a desired thickness. In some embodiments, the deposition time can be about 2 to about 200 seconds, or about 3 to about 100 seconds, or about 5 to about 50 seconds. In some embodiments, a desired thickness of the silicon-containing layer can be less than about 1 nm, or about 1 to about 10 nm, or about 2 to about 6 nm.

For some embodiments, deposition of the silicon-containing layer can occur by flowing one or more silicon-containing precursors into the process chamber housing the substrate. The silicon-containing precursors are transported to the substrate surface where they are adsorbed by the substrate and thermally decomposed to form a highly conformal silicon-containing layer. In some embodiments, forming a silicon-containing layer by CVD may involve controlling the deposition pressure ranging about 0.1 to about 40 Torr, or about 0.5 to about 20 Torr. Substrate temperature during the deposition may be controlled to be about 300 to about 700° C., or about 400 to about 650° C. After deposition, a step coverage for the silicon-containing layer may be at least about 85%. In some embodiments, a step coverage may be at least about 90% or at least about 95%

According to some embodiments, the silicon-containing layer may be conformally deposited along a top surface, sidewalls, and a bottom surface of a feature. Sidewalls may include upper sidewalls and lower sidewalls. “Upper” and “lower” do not specifically define the depth with reference to the top of the feature. Instead, “upper” and “lower” may refer to any relative location with respect to each other, and may be any depth. In one example, depending on the embodiments, upper sidewalls may refer to the depth that reaches about 0.1% to about 90% of the depth from the top of the feature, and lower sidewalls may refer to the depth that reaches about 90% to about 100% of the depth from the top of the feature. In another example, the upper sidewall may refer to the depth that reaches about 0.1% to about 30% of the depth from the top of the feature, and the lower sidewall may refer to the depth that reaches about 30% to about 100% of the depth from the top of the feature. In some embodiments, upper sidewalls and lower sidewalls may be defined by a penetration depth of oxygen-containing species which will described herein. For example, upper sidewalls may refer to the depth in a silicon-containing layer from the top of the feature where oxygen-containing species are adsorbed and diffused, and lower sidewalls may refer to a portion of the sidewalls where oxygen-containing species are not present.

Without being limited by any theory, silicon-containing precursors having low sticking coefficients may be capable of producing highly conformal silicon layer. “Sticking coefficient” is a term used to describe the ratio of the number of adsorbate species (e.g., fragments or molecules) that adsorb/stick to a surface compared to the total number of species that impinge upon that surface during the same period of time. The symbol Se is sometimes used to refer to the sticking coefficient. The value of Se is between 0 (meaning that none of the species stick) and 1 (meaning that all of the impinging species stick). Various factors affect the sticking coefficient, including the type of impinging species, surface temperature, surface coverage, structural details of the surface, and the kinetic energy of the impinging species. Certain species are inherently more “sticky” than others, making them more likely to adsorb onto a surface each time the species impinges on the surface. These more sticky species have greater sticking coefficients (all other factors being equal). In some cases, the sticking coefficient of the precursors (at the relevant deposition conditions) may be about 0.05 or less, for example about 0.001 or less.

In various embodiments, the silicon-containing precursor is a silane. Silanes include but are not limited to substituted and unsubstituted silanes, halosilanes, aminosilanes, organosilanes, alkylsilanes, alkylaminosilanes, and alkylhalosilanes. In particular embodiments, the silicon-containing precursor includes a halosilane precursor. In particular embodiments, the silicon-containing precursor includes an aminosilane precursor.

An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di(sec-butylamino)silane (DSBAS), di(isopropylamino)silane (DIPAS), bis(diethylamino)silane (BDEAS), and the like. A further example of an aminosilane is trisilylamine (N(SiH₃)₃). In one example, the silicon-containing precursor is DIPAS. In another example, the silicon-containing precursor is BTBAS.

A silicon-containing precursor can include one or more optionally substituted amino groups, thereby providing a non-limiting amino silane. In one embodiment, the precursor has a formula of (R′)₄₋ₓSi(NR″₂)ₓ, wherein:
x is 1, 2, 3, or 4;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In another embodiment, the precursor has a formula of (R″₂N)ₓ(R′)₃₋ₓSi-L-Si(R′)₃₋ₓ(NR″₂)ₓ, wherein:
each x is, independently, 0, 1, 2, or 3;
L is a linker, such as a covalent bond, optionally substituted aliphatic, optionally substituted heteroaliphatic, optionally substituted aromatic, optionally substituted heteroaromatic, oxy (—O—), imino, or silyl;
each R′ is, independently, H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, silyl, silyloxy, cyanato, isocyanato, cyano, or isocyano, in which any of these may be optionally substituted; and
each R″ is, independently, H, aliphatic, heteroaliphatic, aromatic, heteroaromatic, or amino, in which any of these may be optionally substituted; or optionally in which two R″ can be taken together, with the nitrogen atom to which each is attached, to form an optionally substituted heterocyclyl.

In particular embodiments, L is optionally substituted imino, such as —NR—, in which R is H, optionally substituted aliphatic, optionally substituted alkyl, optionally substituted alkenyl, optionally substituted alkynyl, or optionally substituted aromatic. In other embodiments, L is optionally substituted silyl, such as —SiR₂—, in which each R is, independently, H, optionally substituted aliphatic, optionally substituted alkyl, optionally substituted alkenyl, optionally substituted alkynyl, or optionally substituted aromatic.

In one instance, at least one x is not 0. In another embodiment, x can be 0 (e.g., if L includes a carbon atom or a heteroatom). In yet another embodiment, x is 0; and/or L includes optionally substituted aliphatic, optionally substituted alkylene, optionally substituted alkenylene, optionally substituted alkynylene, optionally substituted heteroaliphatic, optionally substituted heteroalkylene, optionally substituted heteroalkenylene, optionally substituted heteroalkynylene, optionally substituted aromatic, optionally substituted arylene, optionally substituted heteroaromatic, optionally substituted heteroarylene, oxy (—O—), imino, or silyl.

In particular embodiments, at least one R′ or R″ is not H. The precursor can have any useful combination of R′ groups and amino groups (NR″₂) attached to one or more silicon atoms.

In some embodiments, R′ is H, optionally substituted amino (e.g., —NR₂), aliphatic-oxy (e.g., alkoxy or —OR), aliphatic-carbonyl (e.g., alkanoyl or —C(O)R), aliphatic-carbonyloxy (e.g., alkanoyloxy or —OC(O)R), aliphatic-oxycarbonyl (e.g., alkoxycarbonyl or —C(O)OR), silyl (e.g., —SiR₃), aliphatic-oxy-silyl (e.g., alkoxysilyl or —Si(R)ₐ(OR)_{b}), aminosilyl (e.g., —Si(R)ₐ(NR₂)_{b}), silyloxy (e.g., —O—SiR₃), aliphatic-oxy-silyloxy (e.g., alkoxysilyloxy or —O—Si(R)ₐ(OR)_{b}), aminosilyloxy (e.g., —O—Si(R)ₐ(NR₂)_{b}), aromatic (e.g., aryl), aromatic-oxy (e.g., aryloxy or —OR), hydroxyl (—OH), formyl (—C(O)H), and the like. In particular embodiments, each R is, independently, H, optionally substituted aliphatic, optionally substituted alkyl, optionally substituted alkenyl, optionally substituted alkynyl, optionally substituted heteroaliphatic, optionally substituted aromatic, optionally substituted aryl, and optionally substituted heteroaromatic; a≥0; b≥1; and a+b=3. In some embodiments, two R groups can be taken together, with the nitrogen atom to which each is attached, to form an optionally substituted heterocyclyl. In other embodiments, each R is, independently, H, optionally substituted alkyl, optionally substituted alkenyl, optionally substituted alkynyl, or optionally substituted aryl.

In other embodiments, R″ is H, optionally substituted aliphatic, optionally substituted heteroaliphatic, optionally substituted alkyl, optionally substituted silyl, or optionally substituted silyloxy. In some embodiments, R″ is optionally substituted alkyl (e.g., Me, Et, nPr, iPr, sBu, or (Bu). In other embodiments, R″ is —SiR′₃, —SiR₃, —Si(R′)ₐ(OR)_{b}, —Si(R)ₐ(OR)_{b}, —Si(R′)ₐ(NR₂)_{b}, —Si(R)ₐ(NR₂)_{b}, —Si(R′)ₐ(OR)_{b}(NR₂)_{c}, —Si(R)ₐ(OR)_{b}(NR₂)_{c}, —O—SiR′₃, —O—SiR₃, —O—Si(R′)ₐ(OR)_{b}, —O—Si(R)ₐ(OR)_{b}, —O—Si(R′)ₐ(NR₂)_{b}, —O—Si(R)ₐ(NR₂)_{b}, —O—Si(R′)ₐ(OR)_{b}(NR₂)_{c}, or —O—Si(R)ₐ(OR)_{b}(NR₂)_{c} in which each R′ is, independently, H, aliphatic, heteroaliphatic, aromatic, heteroaromatic, amino, hydrazino, azido, hydroxyl, silyl, silyloxy, cyanato, isocyanato, cyano, or isocyano, in which any of these may be optionally substituted; each R is, independently, H, optionally substituted aliphatic, optionally substituted heteroaliphatic, optionally substituted aromatic, or optionally substituted heteroaromatic; each of a, b, and c≥0; and a+b+c=3 or a+b=3 (if c is not present). In particular embodiments, R is H, optionally substituted alkyl, optionally substituted alkenyl, or optionally substituted alkynyl.

The precursor can include at least one R′ group attached to the silicon atom. In one embodiment, the precursor has a formula of (R′)(H)₃₋ₓSi(NR″₂)ₓ, wherein R′ and R″ can be any described herein, and wherein x is 1, 2, or 3. In another embodiment, the precursor has a formula of (R′)(H)₂Si(NR″₂), wherein R′ and R″ can be any described herein. In one embodiment, the precursor has a formula of (R′)(H)Si(NR″₂)₂, wherein R′ and R″ can be any described herein. In another embodiment, the precursor has a formula of (R′)₂(H)Si(NR″₂), wherein R′ and R″ can be any described herein. In yet another embodiment, the precursor has a formula of (R′)₂Si(NR″₂)₂, wherein R′ and R″ can be any described herein. In one embodiment, the precursor has a formula of (R′)₃Si(NR″₂), wherein R′ and R″ can be any described herein.

The precursor can lack an R′ group attached to the silicon atom. In one embodiment, the precursor has a formula of (H)₄₋ₓSi(NR″₂)ₓ, wherein each R″ can independently be any described herein, and wherein x is 1, 2, 3, or 4. In another embodiment, the precursor has a formula of Si(NR″₂) x, wherein each R″ can independently be any described herein. In particular embodiments, each R″ is, independently, aliphatic, heteroaliphatic, aromatic, or heteroaromatic.

The precursor can include one or more hydrogen atoms attached to the silicon atom. In one embodiment, the precursor has a formula of (H)₃Si(NR″₂) or (H)₂Si(NR″₂)₂ or (H)Si(NR″₂)₃, wherein each R″ can independently be any described herein. In particular embodiments, each R″ is, independently, aliphatic, heteroaliphatic, aromatic, heteroaromatic, or amino, in which any of these may be optionally substituted.

The precursor can include a heterocyclyl group having a nitrogen atom. In one embodiment, the formula has a formula of H₃Si-Het, in which Het is an optionally substituted heterocyclyl including at least one nitrogen atom. In particular embodiments, the precursor has a formula of

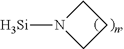

in which the heterocyclyl group can be optionally substituted (e.g., with any substituent described herein as a substitution for alkyl), and wherein n is 1, 2, 3, 4, or 5. In one embodiment, the formula has a formula of R′₃Si-Het, in which Het is an optionally substituted heterocyclyl including at least one nitrogen atom, and each R′ can independently be any described herein. In particular embodiments, the precursor has a formula of

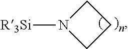

in which the heterocyclyl group can be optionally substituted (e.g., with any substituent described herein as a substitution for alkyl); each R′ can independently be any described herein; and wherein nis 1, 2, 3, 4, or 5.

In some instances, the precursor can have two or more silicon atoms, in which the precursor can include a Si—Si bond. In a particular embodiment, the precursor has a formula of (R″₂N)ₓ(R′)₃₋ₓSi—Si(R′)₃₋ₓ(NR″₂)ₓ, wherein R′ and R″ can be any described herein. In one embodiment, the precursor has a formula of (R″₂N)(R′)₂Si—Si(R′)₂(NR″₂), wherein R′ and R″ can be any described herein. In another embodiment, the precursor has a formula of (R″₂N)₂(R′)Si—Si(R′)(NR″₂)₂, wherein R′ and R″ can be any described herein. In yet another embodiment, the precursor has a formula of (R″₂N)ₓSi—Si(NR″₂)₃, wherein each R″ can independently be any described herein.

The precursor can include differing groups attached to the silicon atoms. In one instance, the precursor has a formula of (R″₂N)ₓ(R′)₃₋ₓSi—SiH₃, wherein R′ and R″ can be any described herein.

A linker can be present between two silicon atoms. In one instance, the precursor has a formula of (R″₂N)ₓ(R′)₃₋ₓSi—NR—Si(R′)₃₋ₓ(NR″₂)ₓ, wherein R′ and R″ can be any described herein, and in which R is H, optionally substituted aliphatic, optionally substituted alkyl, optionally substituted alkenyl, optionally substituted alkynyl, or optionally substituted aromatic. In another instance, the precursor has a formula of (R″₂N)ₓ(R′)₃₋ₓSi—NR—Si(H)₃₋ₓ(NR″₂)ₓ, wherein R, R′, and R″ can be any described herein.

The precursor can include a combination of R′ groups with a linker having a heteroatom. In one instance, the precursor has a formula of (R′)₃Si—NR—Si(R′)₃, wherein R and R′ can be any described herein. In another instance, the precursor has a formula of (R′)₃Si-L-Si(R′)₃, wherein L and R′ can be any described herein. In particular embodiments, L is oxy (—O—), optionally substituted imino (e.g., —NR—), or optionally substituted silyl (e.g., —SiR₂—).

The precursor can include any useful combination of R′ and NR″₂ groups in combination with two silicon atoms. In one instance, the precursor has a formula of (R″₂N)(R′)₂Si-L-Si(R′)₂(NR″₂)ₓ, wherein L, R′, and R″ can be any described herein.

The precursor can include heterocyclic groups including the silicon and nitrogen atoms. In one embodiment, the precursor has a formula of

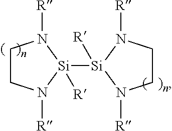

wherein R′ and R″ can be any described herein, and wherein n is 1, 2, 3, or 4.

In another embodiment, the precursor has a formula of

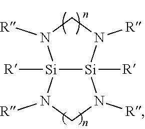

wherein R′ and R″ can be any described herein, and wherein n is 1, 2, 3, or 4. In yet another embodiment, the precursor has a formula of

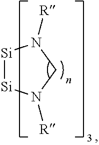

in which each R″ can independently be any described herein; and wherein n is 1, 2, 3, or 4.

In another embodiment, the precursor has a formula of

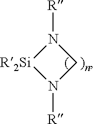

wherein R′ and R″ can be any described herein, and wherein n is 1, 2, 3, or 4. In yet another embodiment, the precursor has a formula of

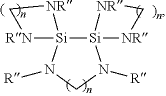

wherein R″ can independently be any described herein, and wherein n is 1, 2, 3, or 4.

In any precursor herein, two R″ can be taken together, with the nitrogen atom to which each is attached, to form an optionally substituted heterocyclyl.

Precursors can include any of the following, e.g., (R^{Ak})₂Si(NH₂)(NR^{Ak}₂)₂, (R^{Ak})₂Si(NR^{Ak}₂)₃, (R^{Ak})₂Si(NHR^{Ak}₂)₂, (R^{Ak})(H)Si(NHR^{Ak})₂, (R^{Ak})₃Si(NR^{Ak}₂), (R^{Ak})₃Si(NHR^{Ak}), H₂Si(NHR^{Ak}₂)₂, (R^{Ak})(H)Si(NR^{Ak}₂)₂, HSi(NH₂)(NR^{Ak}₂)₂, HSi(NR^{Ak}₂)₃, Si(NR^{Ak}₂)₄, (R′)(H)Si(NR″₂)₂, (R′)₂Si(NR^{Ak}₂)₂, (R′)₂Si(N[SiH₃]₂)₂, (R′)₂Si(N[SiR″₃]₂)₂, or (R′)₃Si(NHR^{Ak}). In some embodiments, each of R′ and R″, independently, can be any described herein (e.g., H, optionally substituted aliphatic, optionally substituted heteroaliphatic, optionally substituted alkyl, optionally substituted alkenyl, or optionally substituted alkynyl). In other embodiments, each R^{Ak} is, independently, H, optionally substituted aliphatic, optionally substituted heteroaliphatic, optionally substituted alkyl, optionally substituted alkenyl, or optionally substituted alkynyl. In particular embodiments, R^{Ak} is methyl (Me), ethyl (Et), n-propyl (nPr), iso-propyl (iPr), n-butyl (nBu), sec-butyl (sBu), iso-butyl (iBu), tert-butyl (tBu), and the like.

Non-limiting examples of precursor include any of the following: methylaminotrimethylsilane (SiMe₃[NHMe]); dimethylaminodimethylsilane (SiMe₂H[NMe₂]); dimethylaminotrimethylsilane (SiMe₃[NMe₂]); dimethylaminodiethylsilane (SiHEt₂[NMe₂]); dimethylaminotriethylsilane (SiEt₃[NMe₂]); ethylmethylaminodimethylsilane (SiHMe₂[NMeEt]); ethylmethylaminotrimethylsilane (SiMe₃[NMeEt]); ethylmethylaminodiethylsilane (SiHEt₂[NMeEt]); ethylmethylaminotriethylsilane (SiEt₃[NMeEt]); diethylaminomethylsilane (SiH₂Me[NEt₂]); diethylaminoethylsilane (SiH₂Et[NEt₂]); ethylaminotrimethylsilane (SiMe₃[NHEt]); diethylaminodimethylsilane (SiHMe₂[NEt₂]); diethylaminodiethylsilane diethylaminotrimethylsilane (SiMe₃[NEt₂]); diethylaminotriethylsilane (SiEt₃[NEt₂]); iso-propylaminodimethylsilane (SiHMe₂[NHiPr]); iso-propylaminotrimethylsilane (SiMe₃[NHiPr]); iso-propylaminodiethylsilane (SiHEt₂[NHiPr]); iso-propylaminotriethylsilane (SiEt₃[NHiPr]); di-isopropylaminotrimethylsilane (SiMe₃[NiPr₂]); di-iso-propylaminosilane (SiH₃[NiPr₂], C₆H₁₇NSi, or DIPAS); di-iso-propylaminomethylsilane (SiH₂Me[NiPr₂]); di-isopropylaminodimethylsilane (SiHMe₂[NiPr₂]); di-isopropylaminodiethylsilane (SiHEt₂[NiPr₂]); di-isopropylaminotriethylsilane (SiEt₃[NiPr₂]); n-propylaminotrimethylsilane (SiMe₃[NHnPr]); di-sec-butylaminosilane (SiH₃[NsBu₂] or DSBAS); di-sec-butylaminomethylsilane (SiH₂Me[NsBu₂]); iso-butylaminotrimethylsilane (SiMe₃[NHiBu]); n-butylaminotrimethylsilane (SiMe₃[NHnBu]); tert-butylaminodimethylsilane (SiHMe₂[NHtBu]); tert-butylaminotrimethylsilane (SiMe₃[NHtBu]); tert-butylaminodiethylsilane (SiHEt₂[NHtBu]); tert-butylaminotrietbylsilane (SiEt₃[NHtBu]); dicyclohexylaminosilane (SiH₃[NCy₂], in which Cy is cyclohexyl); N-propylisopropylaminosilane (SiH₃[NiPrnPr]); N-methylcyclohexylaminosilane (SiH₃[NMeCy]); N-ethylcyclohexylaminosilane (SiH₃[NEtCy]); allylphenylaminosilane (SiH₃[NAllPh]); N-isopropylcyclohexylaminosilane (SiH₃[NiPrCy]); allylcyclopentylaminosilane (SiH₃[NAllCp]); phenylcyclohexylaminosilane (SiH₃[NPhCy]); cyclohexylaminotrimethylsilane (SiMe₃[NHCy], in which Cy is cyclohexyl); pyrrolyltrimethylsilane (SiMe₃[NHPy], in which Py is pyrrolyl); pyrrolidinotrimethylsilane (SiMe₃[NHPyr], in which Pyr is pyrrolindyl); piperidino trimethylsilane (SiMe₃[NHPip], in which Pip is piperidinyl); piperazinotrimethylsilane (SiMe₃[NHPz], in which Pz is piperazinyl); imidazolyltrimethylsilane (SiMe₃[NHIm], in which Im is imidazolyl); bis(dimethylamino)silane (SiH₂[NMe₂]₂ or BDMAS); bis(dimethylamino) methylsilane (SiMeH[NMe₂]₂); bis(dimethylamino)dimethylsilane (SiMe₂[NMe₂]₂ of BDMADMS); bis(dimethylamino)diethylsilane (SiEt₂[NMe₂]₂); bis(dimethylamino) methylvinylsilane (SiMeVi[NMe₂]₂); bis(ethylamino)dimethylsilane (SiMe₂[NHEt]₂); bis(ethylmethylamino)silane (SiH₂[NMeEt]₂); bis(ethylmethylamino)dimethylsilane (SiMe₂[NMeEt]₂); bis(ethylmethylamino)diethylsilane (SiEt₂[NMeEt]₂); bis(ethylmethylamino) methylvinylsilane (SiMeVi[NMeEt]₂); bis(diethylamino)silane (SiH₂[NEt₂]₂, C₈H₂₂N₂Si, or BDEAS); bis(diethylamino)dimethylsilane (SiMe₂[NEt₂]₂); bis(diethylamino)methylvinylsilane (SiMeVi[NEt₂]₂); bis(diethylamino)diethylsilane (SiEt₂[NEt₂]₂); bis(iso-propylamino) dimethylsilane (SiMe₂[NHiPr]₂); bis(iso-propylamino)diethylsilane (SiEt₂[NHiPr]₂); bis(iso-propylamino)methylvinylsilane (SiMeVi[NHiPr]₂); bis(di-iso-propylamino)silane (SiH₂[NiPr₂]₂); bis(di-iso-propylamino)dimethylsilane (SiMe₂[NiPr₂]₂); bis(di-iso-propylamino)diethylsilane (SiEt₂[NiPr₂]₂); bis(di-iso-propylamino)methylvinylsilane (SiMeVi[NiPr₂]₂); bis(methylamino)silane (SiH₂[NHMe]₂); bis(sec-butylamino)silane (SiH₂[NHsBu]₂); bis(sec-butylamino)methylsilane (SiHMe[NHsBu]₂); bis(sec-butylamino)ethylsilane (SiHEt[NHsBu]₂); bis(tert-butylamino)silane (SiH₂[NHtBu]₂ or BTBAS); bis(tert-butylamino)dimethylsilane (SiMe₂[NHtBu]₂); bis(tert-butylamino) methylvinylsilane (SiMeVi[NHtBu]₂); bis(tert-butylamino)diethylsilane (SiEt₂[NHtBu]₂); bis(1-imidazolyl)dimethylsilane (SiMe₂[Im]₂, in which Im is imidazolyl); tris(dimethylamino)silane (SiH[NMe₂]₃ or 3DMAS); tris(dimethylamino)phenylsilane (SiPh[NMe₂]₃); tris(dimethylamino)methylsilane (SiMe[NMe₂]₃); tris(dimethylamino)ethylsilane (SiEt[NMe₂]₃); tris (ethylmethylamino)silane (SiH[NEtMe]₃); tris(diethylamino)silane (SiH[NEt₂]₃); tris(iso-propylamino)silane (SiH[NHiPr]₃, C₉H₂₅N₃Si, or TIPAS); tris(dimethylamino)silylamide (Si[NMe₂]₃[NH₂]); tetrakis(dimethylamino)silane (Si[NMe₂]₄); tetrakis(ethylmethylamino)silane (Si[NEtMe]₄); tetrakis(diethylamino)silane (Si[NEt₂]₄); 1,2-diethyl-tetrakis(diethylamino) disilane ([Et₂N]₂EtSi—SiEt[NEt₂]₂); 1,2-dimethyl-tetrakis(dimethylamino)disilane ([Me₂N]₂MeSi—SiMe[NMe₂]₂); 1,2-dimethyl-tetrakis(diethylamino)disilane ([Et₂N]₂MeSi—SiMe[NEt₂]₂); hexakis(methylamino)disilane ([MeHN]₃Si—Si[NHMe]₃); hexakis(ethylamino)disilane ([EtHN]₃Si—Si[NHEt]₃); hexakis(dimethylamino)disilazane (Me₂N—Si[NMe₂]₂—Si[NMe₂]₂—NMe₂), and the like.

In some embodiments, the silane precursor is a halosilane precursor. A halosilane precursor is defined as a precursor having at least one halogen-containing atom and at least one silicon atom. Halogens include chlorine, fluorine, bromine, and iodine. In some embodiments, the halosilane precursor includes a structure of formula (I):

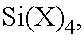

wherein at least one X includes a halogen atom.

For example, one halosilane is tetrachlorosilane or silicon tetrachloride (SiCl₄). Another example of a chemical formula of a halosilane is SiₙX_{y}H_{z} where X is a halogen and His hydrogen; n is an integer greater than or equal to 1 and is equal to the number of Si atoms in the molecule; in some embodiments, y is about 1 to about 4, and z is 4-y. Additional examples include but are not limited to SiHCl₃, SiH₂Cl₂, and SiH₃Cl.

Examples of halosilanes are iodosilanes, bromosilanes, chlorosilanes and fluorosilanes. Specific chlorosilanes include but are not limited to tetrachlorosilane, trichlorosilane, dichlorosilane (DCS), monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, hexachlorodisilane (HCDS), and the like.

In some embodiments, the halosilane is carbon-free. In some embodiments, the halosilane is an organic silicon-containing precursor.

In some embodiments, the halosilane precursor (e.g., in formula (I)) has at least one optionally substituted C₁₋₂ haloalkyl group. Non-limiting haloaliphatic groups include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; or —CH₂CX_{y}H_{3-y}, wherein y is 1, 2, or 3, and wherein each X is, independently, halo (F, Cl, Br, or I). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CCl₃), bromomethyl (—CH₂Br), dibromomethyl (—CHBr₂), tribromomethyl (—CBr₃), iodomethyl (—CH₂I), diiodomethyl (—CHI₂), triiodomethyl (—CI₃), bromofluoromethyl (—CHFBr), chlorofluoromethyl (—CHFCl), fluoroiodomethyl (—CHFI), 2-fluoroethyl (—CH₂CH₂F), 2-chloroethyl (—CH₂CH₂Cl), 2-bromoethyl (—CH₂CH₂Br), 2-iodoethyl (—CH₂CH₂I), 2,2-difluoroethyl (—CH₂CHF₂), 2,2-dichloroethyl (—CH₂CHCl₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes β-halo-substituted ethyl. Yet other haloaliphatic groups include C₁₋₄ haloalkyl, C₂₋₄ haloalkenyl, and C₂₋₄ haloalkynyl.

In addition to silicon-containing precursors, the processing region above the substrate may include plasma species, such as one or more radical species, which may be in a substantially low energy state. One or more radicals may include hydrogen radicals, nitrogen radicals, oxygen radicals, amine radicals, carbon radicals, or a combination thereof. Radical may also be referred to as atom radical or radical species. For example, hydrogen radicals may also be referred to as hydrogen atom radicals or hydrogen radical species. In some embodiments, all, or substantially all, or a substantial fraction of the hydrogen atom radicals can be in the ground state, e.g., at least about 90% or 95% of the hydrogen atom radicals adjacent the substrate may be in the ground state.

Radicals may be generated in a plasma source and introduced into the process chamber. In some implementations, when the excited hydrogen atom radicals lose their energy, or relax, the excited hydrogen atom radical may become a substantially low energy state hydrogen atom radical or a ground state hydrogen atom radical. Hydrogen atom radicals in a substantially low energy state or ground state can be capable of breaking Si—H and/or Si—Si bonds while generally preserving Si—O, Si—N, and/or Si—C bonds. In some implementations, process conditions may be provided so that excited hydrogen atom radicals lose energy or relax to form substantially low energy state or ground state hydrogen atom radicals.

The silicon-containing precursors and the source gas for the hydrogen radicals may be delivered with other species, including carrier gas. Example carrier gases include but are not limited to argon (Ar), helium (He), neon (Ne), krypton (Kr), and xenon (Xe). The concentration of carrier gas can be substantially greater than the concentration of the source gas. As used herein, “substantially greater” with respect to the concentration of carrier gas relative to source gas can refer to a percentage by volume that is at least three times greater. By way of an example, hydrogen gas may be provided in a helium carrier gas at a concentration of about 1 to about 50% hydrogen. The presence of the carrier gas can contribute to increased ionization of the source gas and reduced recombination. Though lower pressure typically facilitates increased ionization of the source gas and reduced recombination, the presence of the carrier gas can serve the same effect. Even at a higher pressure, a substantial fraction of radicals may be generated with minimal recombination when a carrier gas such as helium is flowed with the source gas. Higher pressure in the process chamber during deposition may improve the conformality of a silicon-containing layer. Higher pressure in the process chamber may correspond to a pressure range of about 1 to about 10 Torr, or about 1 to about 5 Torr. Substrate temperature during a silicon-containing layer deposition may be controlled to be about 100 to about 400° C., or about 200 to about 300° C.

In operation 130, a portion of the silicon-containing layer is exposed to oxygen-containing species to form a silicon oxide-containing portion of the silicon-containing layer. In some embodiments, an exposed surface of the silicon-containing layer is exposed to oxygen-containing species. Examples of the oxygen-containing species include oxygen containing gas, e.g., ozone, oxygen, hydrogen peroxide, oxygen-containing radicals, plasmas thereof, or mixtures thereof. Oxygen-containing radicals may include oxygen-containing species generated from a plasma. In one example, ozone, oxygen, or hydrogen peroxide may be provided from one or more gas supplies into the process chamber. In another example, oxygen radicals may be provided from a remote plasma, such as an oxygen plasma, generated in a remote plasma source, which is separated from the process chamber. In some embodiments, a remote plasma source may be used to generate an oxygen plasma. In another example, the oxygen radicals may be generated in the process chamber housing the substrate, such as in the processing region over a substrate.

The oxygen-containing species may be adsorbed on the silicon-containing layer in the recessed feature. Once adsorbed, the oxygen-containing species may diffuse into the silicon-containing layer. The diffusion of the oxygen-containing species may occur in any direction. In some examples, when the oxygen-containing species are provided from above the feature, such as from the remote plasma source located upstream of the process chamber where the exposed surface of the substrate including the features faces a showerhead over the substrate and the plasma species are delivered through the showerhead, at least a portion of oxygen-containing species may be received by a top surfaces of the recessed feature, and may diffuse in a downward direction towards the substrate surface while some of oxygen-containing species may diffuse in a horizontal direction, or any direction where the oxygen-containing species find their way in the silicon-containing layer. The diffusion of the oxygen-containing species may continue up to the point where a penetration depth is reached. The penetration depth may vary depending on the process parameters. One critical parameter may be the chamber pressure during oxidation step in operation 130. In some embodiments, the chamber pressure during the partial oxidation of the silicon-containing layer may be about 0.02 to about 20 Torr, or about 0.02 to about 10 Torr, or about 0.03 to about 10 Torr, or about 1 to about 20 Torr, or about 0.5 to about 5 Torr. The penetration depth may also depend on the time period during which the silicon-containing layer is exposed to the oxygen-containing species. For example, the oxygen-containing species may diffuse in a downward direction, and deeper penetration depth may be achieved when exposure is performed using longer exposure time. The penetration depth may also depend on the composition of a silicon-containing layer, or substrate temperature.

In some embodiments, the penetration depth of the oxygen-containing species may be on the order of nanometers. For example, the penetration depth may be several nm, or in excess of 10 nm. The number (or density) of oxygen-containing species in the silicon-containing layer may be proportional to the time period during which the silicon-containing layer is exposed to the oxygen-containing species.

The penetration depth of the oxygen-containing species may be about 1 to about 50%, or about 1 to about 40%, or about 1 to about 30%, or about 1 to about 20%, or about 1 to about 10%, or about 1 to about 5% of the depth from the top of the feature.

In some embodiments, carbon elements in the silicon-containing layer may be replaced by the oxygen-containing species. For example, carbon elements in Si—C bonds in the silicon-containing layer may be replaced with oxygen-containing species, e.g., oxygen radicals in oxygen plasma, thereby forming Si—O bonds. This oxidation reaction may form a silicon oxide-containing portion comprising silicon oxide. The silicon oxide-containing portion refers to an oxidized portion in the silicon-containing layer. The silicon oxide-containing portion (i.e., oxidized portion) may include at least a silicon component and an oxygen component chemically bonded to each other, forming one or more Si—O bonds, and may have a chemical formula of SixOy, where x≥1, and y≥1. The silicon oxide-containing portion (i.e., oxidized portion) may be a substantially carbon-depleted, or have significantly reduced carbon content, relative to as-deposited silicon-containing layer. For example, the silicon oxide-containing portion may have a carbon-depleted, or substantially carbon-depleted composition after being exposed to, and oxidized by the oxygen radicals. In one example, about 10 to about 40% of carbon elements in the Si—C bonds in an oxidized portion may be replaced by oxygen. In some embodiments, silicon oxycarbide layer may be deposited in the recessed feature. In some embodiments, hydrogen may be incorporated into silicon oxycarbide during deposition. Silicon oxycarbide may include undoped and doped silicon oxycarbide and the doped silicon oxycarbide may include hydrogenated silicon oxycarbide. After silicon oxycarbide is exposed to, and oxidized by oxygen radicals in the oxygen plasma, silicon oxycarbide may include an silicon oxide-containing portion including silicon oxide (e.g., silicon oxide-containing portion) or silicon oxycarbide with significantly reduced carbon content relative to as-deposited silicon oxycarbide.

In some embodiments, the oxygen-containing species may be provided through the top surface of the feature, the distribution of oxygen-containing species may be greater for the silicon-containing layer deposited at or near the top surface of the feature, and may decrease with the depth down to the penetration depth, beyond which the number of the oxygen-containing species may drop to zero or to substantially zero. In one example, silicon oxycarbide, deposited in the recessed surfaces, e.g., upper sidewalls and lower sidewalls, in a trench may be exposed to oxygen-containing species. After oxidation, silicon oxycarbide on the top surface and upper sidewalls may be deprived of carbon, and its composition may be modified to silicon oxide. The silicon-containing layer deposited on the lower sidewalls and/or bottom surfaces in the trench may not be oxidized.

In operation 140, the silicon oxide-containing portion from operation 130 may be etched from the silicon-containing layer. In some embodiments, operation 140 may cause formation of a partially etched silicon-containing layer. A partially etched silicon-containing layer refers to a silicon-containing layer that has undergone at least one oxidation and etch operation. A partially etched silicon-containing layer is a silicon-containing layer that is not provided with oxygen-containing species, thereby not removed in the subsequent etch operation by one or more etch chemistries such as hydrogen fluoride. A partially etched silicon-containing layer may be a silicon-containing layer that is located beyond the penetration depth, thereby not being oxidized or not provided with silicon-oxygen bond. A partially etched silicon-containing layer may be located at the lower sidewalls or bottom surface in the recessed feature where oxygen-containing species are introduced from the showerhead over the substrate. On the other hand, a partially etched silicon-containing layer may also be formed on the top surface or upper sidewall surfaces of the recessed features depending on the conditions by which oxygen-containing species are introduced in the recessed feature. A partially etched silicon-containing layer may refer to a partially filled gap (e.g., trench or hole or via) in one or more features. Completely filled features or features with a completely filled gap may refer to features where the level of the silicon-containing layer in a gap (e.g., trench or hole or via) is similar to, or above the level of the top surface of the feature. Completely filled features may be devoid of voids, and therefore dense. In some embodiments, depending on the deposition parameters and/or deposition route, completely filled features may include one or more voids formed in the gapfill materials (e.g., silicon-containing material).

During etching, any suitable etchant may be used. In some embodiments, hydrogen fluoride (HF) or other etch reactants may be used as an etch chemistry. A silicon-containing layer (e.g., SiOC) or ruthenium may be resistant to HF etch. The etch chemistry may be configured to selectively etch silicon oxide without noticeably reacting with other adjacent materials. For example, the etch selectivity with respect to silicon nitride may be further increased by adding amines. A substrate including a silicon-containing layer, after exposure to oxygen-containing species, may be immersed in a diluted HF solution for etching an silicon oxide-containing portion. Other portions not exposed to oxygen-containing species in a silicon-containing layer may not be etched by hydrogen fluoride or other etch reactants. A diluted HF solution may be provided as vapor at an elevated temperature to etch an silicon oxide-containing portion of the silicon-containing layer in gas phase. A diluted HF solution may be atomized to etch an silicon oxide-containing portion of the silicon-containing layer. Vaporized or atomized HF may be diluted to a concentration suitable for etching the silicon oxide-containing portion in a silicon-containing layer. In some embodiments, silicon tetrafluoride (SiF₄) may be generated as a reaction byproduct from the reaction between hydrogen fluoride and silicon oxide. Other etch reactants may include nitrogen fluoride (NF₃), tetrafluoromethane (CF₄), trifluoromethane (CHF₃), difluoromethane (CH₂F₂), fluoromethane (CH₃F), carbon hexafluoride (C₂F₆), octafluoropropane (C₃F₈), octafluorocyclobutane (C₄F₈), hexafluorocyclobutene (C₄F₆), 1,2,3,3,4-pentafluorocyclobutene-4-ylradical (C₄F₅), or mixtures thereof.

During this operation, an oxidized silicon-containing layer (also referred to as a silicon oxide-containing portion) on the top surface and/or upper sidewalls may be etched away, while as-deposited silicon-containing layer not exposed to oxygen-containing species or penetrated by the oxygen-containing species may remain on the lower sidewalls and/or bottom surfaces without substantial composition change, thereby forming a partially etched silicon-containing layer at the lower sidewalls and/or bottom surfaces in the feature. The partially etched silicon-containing layer may have the same composition as the as-deposited silicon-containing layer. In some embodiments, the partially etched silicon-containing layer after etching may be a conformal layer.

Operations 120-140 may be repeated one or more times to achieve desirable deposition properties. In some embodiments, operations 120-140 are repeated to control the deposition of a silicon-containing layer (or silicon-containing material) in the recessed features, which may be filled by the silicon-containing material. By repeating the cycle including operations 120-140, a gapfill process may be advanced until a gapfill process for filling features or gaps with the silicon-containing material is complete. The advancement of gapfill process may be determined by monitoring the level of silicon-containing layer at the end of each cycle. As the cycle progresses, the level of silicon-containing layer, measured from the bottom of the feature, may increase. After a predetermined number of cycles, the level may be substantially the same as or above the height of the feature, at which point a gapfill may be considered to be complete. Herein, the “level” of a silicon-containing layer may refer to the thickness of the silicon-containing layer after etching of silicon-containing layer in the recessed feature. The thickness of the silicon-containing layer may be the distance between the bottom of the feature and the lowest point of the silicon-containing layer within the gap (or volume) in the feature.

Returning to repeating the cycle for a gapfill process, after forming a partially etched silicon-containing layer in operation 140 in the first cycle, a silicon-containing layer may be conformally deposited in the feature in operation 120 in a second cycle. For example, the silicon-containing layer may be deposited on the top surface and the upper sidewalls in the recessed features, where the silicon-containing layer was deposited and etched in the first cycle. The silicon-containing layer may also be deposited over the top of the partially etched silicon-containing layer formed in operation 140 in the first cycle, thereby increasing the level of the layers that are gap filled in the trench. The silicon-containing layer deposited in operation 120 in the second cycle may be conformal, and may not include seams and/or voids. In some embodiments, the silicon-containing layer in the second cycle may not be fully conformal. For example, in some embodiments, one or more seams and/or voids may remain in the silicon-containing material after gapfill is complete. The chemical composition of the silicon-containing layer deposited in operation 120 in the second cycle may be the same or substantially the same as that of the partially etched silicon-containing layer formed at operation 140 in the first cycle. In operation 130, oxygen-containing species may be provided to the silicon-containing layer which may replace carbon elements in Si—C bonds in the silicon-containing layer with oxygen, thereby forming a silicon oxide with Si—O bonds. This oxidation reaction may be limited to the silicon-containing layer that was exposed to oxygen-containing species in some embodiments.

The penetration depth in operation 130 may control the advancement of gapfill. In some embodiments, the penetration depth in operation 130 in the second cycle may be configured to be shorter than the penetration depth in the first cycle. That way, the distance the oxygen-containing species diffuse from the top surface of the feature in a downward direction may also be shorter than in the first cycle. The silicon-containing layer below the penetration depth may not be oxidized and, therefore, may not be etched in operation 140. After operation 140, the level of the remaining silicon-containing layer may be higher than the level after the first cycle, thereby advancing gapfill. Etch conditions in operation 140 in the second cycle may be substantially similar to those in the first cycle. For example, HF or other etch reactants in liquid or vapor (or atomized) form may selectively etch a silicon oxide-containing portion relative to other materials on the substrate. Other etch reactants may include nitrogen fluoride (NF₃), tetrafluoromethane (CF₄), trifluoromethane (CHF₃), difluoromethane (CH₂F₂), fluoromethane (CH₃F), carbon hexafluoride (C₂F₆), octafluoropropane (C₃F₈), octafluorocyclobutane (C₄F₈), hexafluorocyclobutene (C₄F₆), 1,2,3,3,4-pentafluorocyclobutene-4-ylradical (C₄F₅), or mixtures thereof. Operations 120-140 may be repeated until gapfill is advanced to the top surface of the feature in operation 150. In some embodiments, operations 120-140 may be repeated until the silicon-containing layer may fill the gap above the top surface of the feature. Any excess silicon-containing layer above the top surface may be removed by chemical mechanical planarization (CMP).

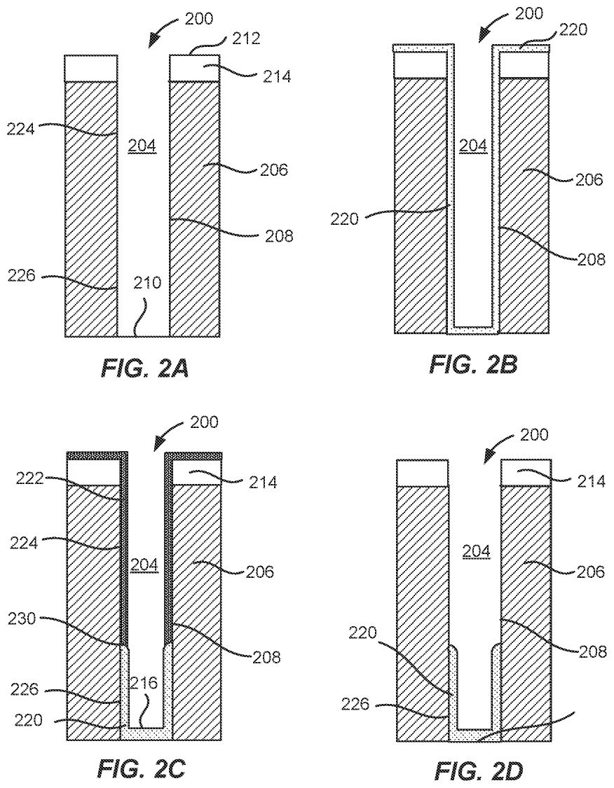

FIGS. 2A-2D are cross-sectional schematic illustrations of a feature of an example substrate undergoing gapfill according to some embodiments. The operations of gapfill may include additional, fewer, or different operations than shown in FIGS. 2A-2D. FIG. 2A shows an example of a feature 200 of a semiconductor substrate with a trench (or hole or volume or gap) 204 formed between adjacent structures 206 including sidewalls 208 including upper sidewalls 224 and lower sidewall 226, a bottom surface 210, and a top surface 212. The structure 206 may be an array of metal lines. In some embodiments, the structure 206 may include ruthenium (Ru). A Ru structure may be deposited by any suitable method such as CVD, ALD, or physical vapor deposition (PVD) such as sputtering. In some embodiments, one or more additional layers may be formed on top of the structure 206 to form the top surface 212. The one or more layers may include nitride hardmask 214. The nitride hardmask 214 may be formed by PECVD. In some embodiments, depending on the device application, the pitch for this feature 200 may be about 20 nm, and the gap may be about 10 nm or less. The height of the feature 200 may be about 30 to about 200 nm, or about 50 to about 200 nm.

FIG. 2B illustrates a silicon-containing layer 220 formed in the feature 200. The silicon-containing layer 220 may be formed along the top surface 212, sidewalls 208, and bottom surface 210 in the trench 204 by any suitable deposition technique, for example, CVD, PECVD, ALD, or PEALD. In one example, the silicon-containing layer 220 may be silicon carbide, silicon oxycarbide, hydrogenated silicon oxycarbide (SICOH), or silicon oxycarbonitride. The silicon-containing layer 220 may be a conformal layer having a high step coverage. The thickness of the silicon-containing layer 220 deposited in the recessed feature 200 may be about 0.3 to about 5 nm, or about 0.5 to about 4 nm, or about 0.7 to about 3 nm.

FIG. 2C shows a portion of the silicon containing layer is oxidized by after exposure to oxygen-containing species. Oxygen-containing species may include oxygen, ozone, hydrogen peroxide, plasmas thereof, oxygen-containing radicals (which may be generated from plasmas thereof), or mixtures thereof. In one example, oxygen radicals may be generated from an oxygen plasma. In one example, the oxygen plasma may be formed in a remote plasma source located upstream of the process chamber, and may be provided through a showerhead in a downward direction toward the semiconductor substrate. Oxygen, ozone, or hydrogen peroxide may be provided from one or more gas supplies, or an atomizer fluidly connected to the process chamber, and may be adsorbed on the surface of recessed features and other surface on the semiconductor substrate. During exposure to the oxygen-containing species, the oxygen-containing species may diffuse into the silicon-containing layer 220. The oxygen-containing species may diffuse in any direction. Some of oxygen-containing species may diffuse in a downward direction toward the bottom 210 of the feature 200 up to a certain distance, i.e., penetration depth. The oxygen-containing species in the silicon-containing layer 220 may react with carbon elements in Si—C bonds in the silicon-containing layer 220. In some embodiments, carbon elements in Si—C may be replaced by the oxygen-containing species to form a silicon oxide-containing portion 222 including Si—O bonding. Carbon may be removed from the silicon-containing layer 220 during the exposure. The silicon oxide-containing portion 222 may be a portion of the silicon-containing layer that is exposed by the oxygen-containing species. In one example, the silicon oxide-containing portion 222 may be formed on the top surface 212 and/or upper sidewalls 224, where carbon elements in Si—C bonds are replaced by the oxygen-containing species. The silicon oxide-containing portion 222 may include silicon oxide.

A silicon-containing layer 220 formed on the lower sidewalls 226 and/or bottom surface 210 may not be exposed to oxygen-containing species, and may not be oxidized. The composition of the silicon-containing layer 220 may be the same as the as-deposited silicon-containing layer 220. The penetration depth of the oxygen-containing species may control the depth of an oxidized silicon-containing layer. Extended penetration depth may increase the volume of an oxidized silicon-containing layer which is subsequently etched, and decrease the volume of an as-deposited silicon-containing layer. Reduced penetration depth may decrease the volume of an oxidized silicon-containing layer, and increase the volume of an as-deposited silicon-containing layer. For example, the penetration depth may be configured to be above level 216 of the silicon-containing layer in the feature 200. It will be understood that FIG. 2C is merely a schematic for distinguishing the silicon oxide-containing portion 222 from the silicon-containing layer 220 that is not oxidized (i.e., as-deposited), and a profile of the penetration depth, which is shown as a borderline 230 between the silicon oxide-containing portion 222 and the un-oxidized silicon-containing layer 220 may not be limiting. For example, the borderline 230 may not be limited to an arc-shaped. The borderline 230 may be, for example, a taper.

FIG. 2D shows a partially etched silicon-containing layer in the recessed feature after etching operation. After oxidation as shown in FIG. 2C, the silicon oxide-containing portion 222 in the silicon-containing layer may be selectively etched relative to other adjacent materials, e.g., ruthenium 206, a silicon-containing layer (e.g., silicon oxycarbide) 220 that is not oxidized, or nitride hardmask 214. This selective etching may lead to the formation of the silicon-containing layer 220 that is not exposed to the oxygen-containing species, and therefore not oxidized. After an etch operation, the composition of the silicon-containing layer 220 may remain the same as the as-deposited composition. Selective etching may be performed by immersing the feature 200 in a dilute HF solution or spraying a dilute HF solution to the substrate at atmospheric temperature or elevated temperature.

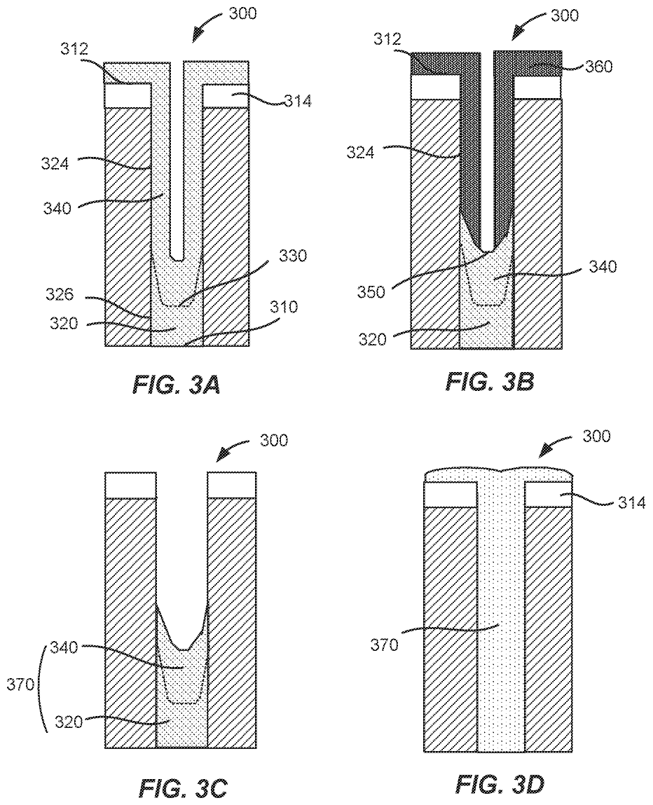

FIGS. 3A-3D are cross-sectional schematic illustrations of a feature of an example substrate undergoing a second or any gapfill following the first gapfill according to some embodiments. For example, FIGS. 3A-3D show gapfill for a feature where at least one silicon-containing layer is already formed. The operations of gapfill may include additional, fewer, or different operations than shown in FIGS. 3A-3D.

FIG. 3A illustrates that the feature 300 includes a first partially etched silicon containing layer 320 formed prior to deposition of the silicon-containing layer 340. It is to be appreciated that the depth and profile of the silicon-containing layer 320 may be non-limiting. The first partially etched silicon containing layer 320 may be formed on the lower surface 310 and lower surface 326 with the level 330. The silicon containing layer 340 may be deposited in the recessed feature 300. For example, the silicon containing layer 340 may be deposited on the upper sidewalls 324, on the top surface 512, and on top of the first partially etched silicon-containing layer 320, thereby filling the gap and increasing the level of the silicon-containing layer in the gap relative to the previous gapfill. The composition of the silicon containing layer 320 may be identical to that of the silicon-containing layer 340. The silicon containing layer 340 may be conformally deposited in the recessed feature 300 without forming seams and/or voids.

The silicon-containing layer 340 may be deposited in the recessed feature using any suitable deposition technique, for example, CVD, PECVD, ALD, PEALD, or other technique. The first partially etched silicon-containing layer 320 may be or include silicon oxycarbide, hydrogenated silicon oxycarbide (SiCOH), silicon oxynitride, or silicon oxycarbonitride. In some embodiments, the composition of the silicon-containing layer 340 may be the same as the composition of the partially etched silicon-containing layer 320.

At FIG. 3B, the silicon-containing layer 340 in FIG. 3A may be exposed to oxygen-containing species for at least partially oxidizing the silicon-containing layer 340. In some embodiments, oxygen-containing species may be oxygen, ozone, hydrogen peroxide, oxygen-containing radicals, plasmas thereof, or mixtures thereof. In some embodiments, the penetration depth of the oxygen-containing species from the top surface of the feature 300 may be adjusted to be shorter than the penetration depth for the first partially etched silicon-containing layer 320. For example, the penetration depth may be configured such that the oxygen-containing species in FIG. 3B may not diffuse below level 350. In this example, oxidation reaction may be limited to a portion near to or above the level 350, leading to an silicon oxide-containing portion 360. The silicon oxide-containing portion 360 may include the silicon-containing layer formed on the upper sidewalls 324 and the on the top surface 512. The silicon-containing layer 340 outside the penetration depth may not be exposed to the oxygen-containing species, therefore may not be oxidized. The composition of the silicon-containing layer 340 may not be modified, and may be identical to as-deposited composition.

FIG. 3C illustrates a second partially etched silicon-containing layer 370 after the silicon oxide-containing portion 360 is etched. The second partially etched silicon-containing layer 370 may include the first partially etched silicon-containing layer 320 and the silicon-containing layer 340 that is not oxidized. In some embodiments, after an etch operation, the level 350 of the second partially etched silicon-containing layer 370 is higher relative to the level 330 of the first partially etched silicon-containing layer 320, advancing a gapfill. The etching conditions of the silicon oxide-containing portion 360 may be substantially similar to those for forming the first partially etched silicon-containing layer 320.

In some embodiments, a gapfill cycle including deposition, oxidation, and etch, for example, as shown in FIGS. 2B-2D and/or 3A-3C may be repeated until gapfill is complete. In some embodiments, a gapfill of the recessed feature may be complete when the level of the silicon-containing layer is substantially similar to, or above the level of the nitride hardmask 514. FIG. 3D illustrates a cross-sectional schematic of a feature where a gapfill is completed after repeating gapfill cycles multiple times according to some embodiments. In each cycle, conformal deposition of the silicon-containing layers may lead to a gapfill without forming seams and/or voids. The silicon-containing layers formed in each gapfill cycle may have same compositions.

The number of gapfill cycles may depend on the deposition parameters including the deposition precursor, reactant ions and/or radicals, byproduct, and/or parameters controlling the penetration depth. For example, extended penetration depth of oxygen-containing species may increase the volume of the silicon oxide-containing portion which is subsequently etched. That condition will etch the silicon-containing layer to a deep depth, and may involve increased number of gapfill cycles including deposition, oxidation, and etch before completing a gapfill. Reduced penetration depth may also reduce the volume of the silicon-containing layer that is exposed to the oxygen-containing species. That will etch the silicon-containing layer to a shallow depth.

After repeating gapfill cycles, excess silicon-containing layer may be formed above the top surface 512 of the feature 300. In some embodiments, the silicon-containing layer 370 may fill a gap and cover the top surface 512 of the feature 300 as shown in FIG. 3D. This excess silicon-containing layer may constitute an overburden. The excess silicon-containing layer above the top surface of the feature 300 may be removed by CMP process to control the height of the silicon-containing layer with respect to the silicon nitride hardmask 114. The number of cycles for complete fill the feature may depend on the pitch, gap width, and/or depth of the trench, silicon-containing layer composition, chamber pressure or the like. For example, the gapfill cycles including silicon-containing layer deposition, oxidation, and etching may be repeated about 3 to about 15 times, or about 4 to about 12 times, or about 5 to about 10 times to conformally fill a feature having a gap of about 10 nm, and a depth of about 100 nm.

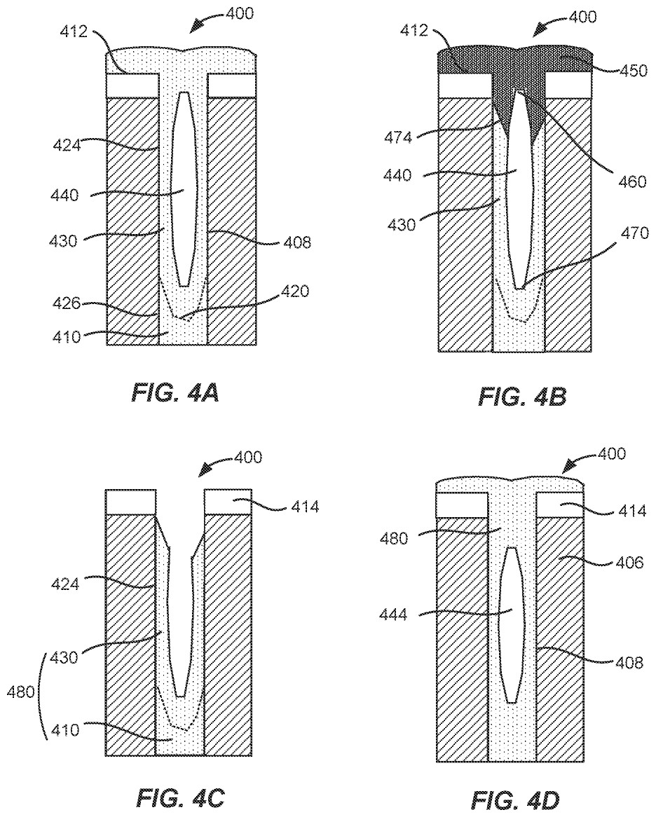

FIGS. 4A-4D are cross-sectional schematic illustrations of a feature of an example substrate undergoing gapfill according to some embodiments. FIGS. 4A-4D illustrate gapfill process based on at least one or more non-conformal depositions of a silicon-containing layer in the recessed feature. The gapfill process shown in FIGS. 4A-4D may begin by receiving a substrate including a feature where at least one silicon-containing layer is conformally deposited, oxidized, and etched according to some embodiments to have a partially etched silicon-containing layer 410 with a level 420. It is to be appreciated that the depth and profile of the silicon-containing layer 410 may be non-limiting.

FIG. 4A illustrates that a non-conformal silicon-containing layer is formed in the recessed feature. In some embodiments, a silicon-containing layer 430 may be deposited on the top surface 412 and sidewalls 408 including an upper sidewalls 424 and lower sidewalls 426 in the feature 400. The silicon-containing layer 430 may also be deposited on top of a first partially etched silicon-containing layer 410 with the level 420 in the feature 400 as shown in FIG. 4A. During the deposition of the silicon-containing layer 430, mass transport limitations may cause “bread-loafing” (or “pinched off′”) deposition that show thicker deposition at top surface 412 and thinner deposition at recessed surfaces such as sidewalls 408. This may cause the top of the feature opening to close before the feature can be completely filled.

In another embodiment, a silicon-containing layer 430 may be deposited without closing the top of the feature opening. Instead, thicker deposition at top surface 412 and thinner deposition at recessed surfaces may be obtained.

Deposition may be performed by ALD. Unlike CVD processes, ALD processes use surface-mediated deposition reaction to deposit films on a layer-by-layer basis, and such films may be typically conformal. On the other hand, although ALD can deposit highly conformal films, deposition of films into high aspect ratio feature can be difficult. The step coverage and uniformity of film along the sidewall depends on, for example, transport of the deposition precursor, reactant ions and/or radicals, and byproducts. As the lateral dimension of the feature narrows, transport and diffusion of the deposition precursor and any reactant species becomes progressively more difficult in the feature. Thus, the top of the feature is exposed to more precursor and reactant species and the bottom of the feature is exposed to fewer precursor and reactant species due to diffusion limitations. This can result in formation of seams and/or voids in a high aspect ratio feature. In some embodiments, the silicon-containing layer 430 may be deposited to intentionally form a void 440 within the gapfill material in the recessed feature as shown in FIG. 4A.

FIG. 4B illustrates the silicon-containing layer in the feature 400 is exposed to oxygen-containing species. The oxygen-containing species may adsorb on and diffuse through the silicon-containing layer 430. Where the oxygen-containing species are provided from above the feature 400, the silicon-containing layer that is formed on the top surface 412, and floating over and filling the entrance of the gap may be oxidized, thereby forming an silicon oxide-containing portion 450. In some embodiments, the penetration depth of the oxygen-containing species may be controlled such that the oxygen-containing species may diffuse to a location between the top 460 and the bottom 470 of the void 440. FIG. 4B illustrates that the penetration depth, which is shown as a borderline 474 between the silicon oxide-containing portion 450 and the silicon-containing layer 430, is closer to the top 460 relative to the bottom 470 of the void 440. FIG. 4B shows the silicon-containing layer 430 is not exposed to oxygen-containing species, therefore is not oxidized. The composition of the silicon-containing layer 430 may not be modified by the oxidation reaction.

FIG. 4C shows a second partially etched silicon-containing layer 480 after the silicon oxide-containing portion 450 is etched. The silicon oxide-containing portion 450 (in FIG. 4B) is etched by a diluted HF solution as described herein. After etch, the resulting feature 400 may have a silicon-containing layer 480 including the first partially etched silicon-containing layer 410 and the silicon-containing layer 430 that is not oxidized by the oxygen-containing species. In some embodiments, the composition of the silicon-containing layer 430 is identical or substantially identical to the first partially etched silicon-containing layer 410. In some embodiments, the composition of the silicon-containing layer 430 may be configured to be different from the first partially etched silicon-containing layer 410 to modify the dielectric property of the gapfill material. In some embodiments, the silicon-containing layer 480 may not be fully conformal. In some embodiments, the upper sidewalls may have a thicker silicon-containing layer and the lower sidewalls may have thinner layer.

A gapfill cycle including deposition, exposure, and etch operations (e.g., operations as shown in FIGS. 4A-4C) may be repeated one or more times. The number of gapfill cycles may depend on the deposition parameters including the deposition precursor, reactant ions and/or radicals, byproduct, and/or parameters controlling the penetration depth. For example, extended penetration depth of oxygen-containing species may increase the volume of the silicon oxide-containing portion which is subsequently etched. That condition will etch the silicon-containing layer to a deep depth, and may lead to increased number of gapfill cycles including deposition, oxidation, and etch before completing a gapfill. Reduced penetration depth may also reduce the volume of the silicon-containing layer that is exposed to the oxygen-containing species and may etch the silicon-containing layer to a shallow depth.

FIG. 4D illustrates a cross-sectional depiction of a feature after a cycle of deposition, exposure, and etch operation (e.g., operations as shown in FIGS. 4A-4C) are repeatedly performed. For example, the silicon-containing layers may be formed non-conformally. The feature opening may have a thicker layer, and the sidewalls of the feature may have a thinner layer. After the feature opening is closed, the silicon-containing layer 480 (i.e., gapfill material having identical composition as the silicon-containing layer) may include a void 444. In some embodiments where the void 444 is formed after depositing the silicon containing layer 430 (as shown in FIG. 4A), the void 444 may be formed to be smaller than the void 400. In some embodiments, processing parameters may be controlled to form seams and/or voids under the top level of the adjacent structure 406. Any excess silicon-containing layer formed above the nitride mask 414 may be removed by CMP to level off the silicon-containing layer with respect to the top of the nitride mask 414. The embodiments shown in FIGS. 4A-4D may have benefits of requiring generally reduced number of gapfill cycles, or controlling (e.g., lowering) the dielectric constant of the silicon-containing layer 480 in the gap formed between the adjacent structures 406.

### Apparatus

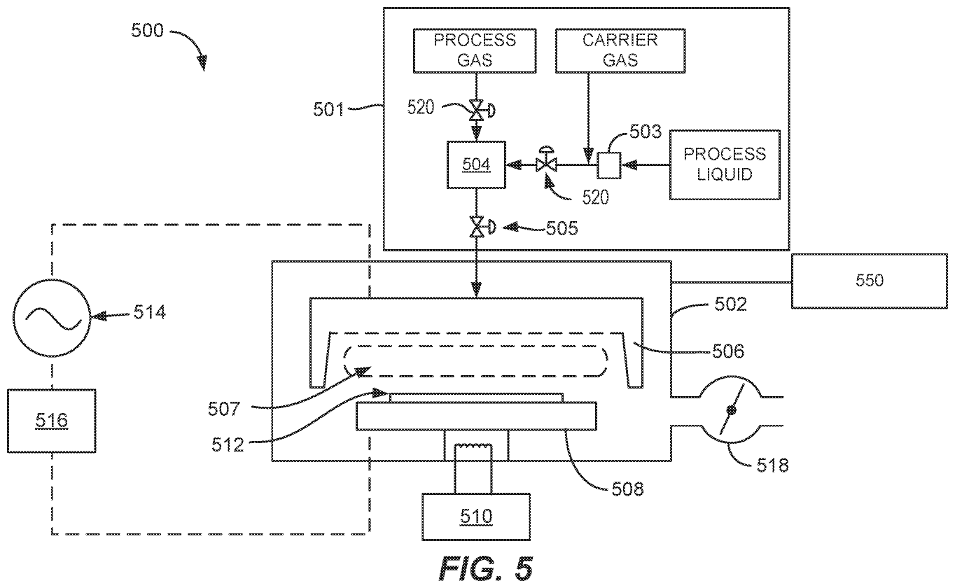

FIG. 5 depicts a schematic illustration of an embodiment of an atomic layer deposition (ALD) process station 500 having a process chamber 502 for maintaining a low-pressure environment. A plurality of ALD process stations 500 may be included in a common low pressure process tool environment. For example, FIG. 5 depicts an embodiment of a multi-station processing tool 500. In some embodiments, one or more hardware parameters of ALD process station 500 including those discussed in detail below may be adjusted programmatically by one or more computer controllers 550.

ALD process station 500 fluidly communicates with reactant delivery system 501 for delivering process gases to a showerhead 506. Reactant delivery system 501 includes a mixing vessel 504 for blending and/or conditioning process gases, such as a silicon-containing precursor gas, nitrogen-containing species, oxygen-containing species, carbon-containing species, or hydrogen-containing species for delivery to showerhead 506. The oxygen-containing species may include oxygen (O₂), ozone (O₃), hydrogen peroxide, carbon monoxide (CO), carbon dioxide (CO₂), nitrogen dioxide (NO₂), nitrous oxide (N₂O), or mixtures thereof. The carbon-containing species may include acetylene (C₂H₂), ethylene (C₂H₄), propene (C₃H₆), or mixtures thereof.

Hydrogen-containing species may include hydrogen (H₂), methane (CH₄), ethane (C₂H₆), or mixtures thereof. Nitrogen-containing species may include nitrogen (N₂), ammonia (NH₃), diazene (N₂H₂), or hydrazine (N₂H₄), or mixtures thereof. One or more mixing vessel inlet valves 520 may control introduction of process gases to mixing vessel 504. One or more valves 505 may control introduction of gases to the showerhead 506.

As an example, the embodiment of FIG. 5 includes a vaporization point 503 for vaporizing liquid reactant to be supplied to the mixing vessel 504. In some embodiments, vaporization point 503 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 503 may be heat traced. In some examples, mixing vessel 504 may also be heat traced. In one non-limiting example, piping downstream of vaporization point 503 has an increasing temperature profile extending from approximately 40° C. to approximately −55° C. or from about 60° C. to about 65° C. at mixing vessel 304.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller (LFC) upstream of vaporization point 503 may be provided for controlling a mass flow of liquid for vaporization and delivery to ALD process station 500. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 506 distributes process gases toward substrate 512. In the embodiment shown in FIG. 5, the substrate 512 is located beneath showerhead 506 and is shown resting on a pedestal 508. Showerhead 506 may have any suitable shape, and may have any suitable number and arrangement of ports for distributing process gases to substrate 512.

In some embodiments, a microvolume 507 is located beneath showerhead X106. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 508 may be raised or lowered to expose substrate 512 to a volume between the substrate 512 and the showerhead 506. It will be appreciated that, in some embodiments, pedestal height may be adjusted programmatically by a suitable computer controller 550.

In another scenario, adjusting a height of pedestal 508 may allow a plasma density to be varied during plasma activation in the process in embodiments where a plasma is ignited. At the conclusion of the process phase, pedestal 508 may be lowered during another substrate transfer phase to allow removal of substrate 512 from pedestal 508.

In some embodiments, pedestal 508 may be temperature controlled via heater 510. In some embodiments, the pedestal 508 may be heated to a temperature of about 25° C. to about 800° C., or about 200° C. to about 700° C., during deposition of silicon nitride films as described in disclosed embodiments. In some embodiments, the pedestal is set at a temperature of about 25° C. to about 800° C., or about 200° C. to about 300° C.

Further, in some embodiments, pressure control for ALD process station 500 may be provided by butterfly valve 518. As shown in the embodiment of FIG. 5, butterfly valve 518 throttles a vacuum provided by a downstream vacuum pump (not shown). However, in some embodiments, pressure control of ALD process station 500 may also be adjusted by varying a flow rate of one or more gases introduced to the ALD process station 500.

In some embodiments, a position of showerhead 506 may be adjusted relative to pedestal 508 to vary a volume between the substrate 512 and the showerhead 506. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers 550.

In some embodiments where plasma may be used as discussed above, showerhead 506 and pedestal 508 electrically communicate with a radio frequency (RF) power supply 514 and matching network 516 for powering a plasma. For example, plasma may be used for treating a silicon oxide surface prior to depositing silicon nitride. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are about 150 W to about 6000 W for a single-station chamber. For a 4-station chamber, the plasma power may include four generator each powered up to about 6000 W, for a total of about 24000 W. For treating a silicon-containing layer, the substrate may be exposed to one or more oxygen-containing species, e.g., oxygen-containing radicals, or a mixture of oxygen-containing species and optional inert gases while igniting a plasma using the RF power supply 514 and matching network 516.

In some embodiments, the substrate may be exposed to nitrogen-containing species, oxygen-containing species, carbon-containing species, or hydrogen-containing species while igniting a plasma to treat a substrate using plasma powers such as about 500 to about 6000 W per surface area of a 300 mm wafer. For example, the substrate surface may be oxidized by exposing the substrate to oxygen-containing species when plasma with plasma powers such as between about 500 to about 6000 W is ignited. The plasma may be generated remotely (such as in a remote plasma generator) or directly in a chamber housing the substrate (i.e. in situ). RF power supply 514 may provide RF power of any suitable frequency. In some embodiments, RF power supply 514 may be configured to control high- and low-frequency RF power sources independently of one another. Example low-frequency RF frequencies may include, but are not limited to, frequencies between 0 kHz and 500 kHz or up to about 2 MHz. Example high-frequency RF frequencies may include, but are not limited to, frequencies between 1.8 MHz and 2.45 GHz, or greater than about 13.56 MHz, or greater than 27 MHz, or greater than 30 MHz, or greater than 60 MHz. It will be appreciated that any suitable parameters may be modulated discretely or continuously to provide plasma energy for the surface reactions.

In some embodiments, the remote plasma generator may be fluidly connected to the reactant delivery system 501. The remote plasma generator may receive one or more nitrogen-containing species, oxygen-containing species, carbon-containing species, or hydrogen-containing species from the reactant delivery system 501. For example, oxygen-containing plasma may be generated while igniting a plasma when oxygen-containing species is supplied to the remote plasma generator. The remote plasma generator may also be fluidly connected to a process chamber 502. In some embodiments, the remote plasma generator may be fluidly connected to the showerhead 506 such that the oxygen-containing plasma may be provided to the substrate in the process chamber 502 via the showerhead 506.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

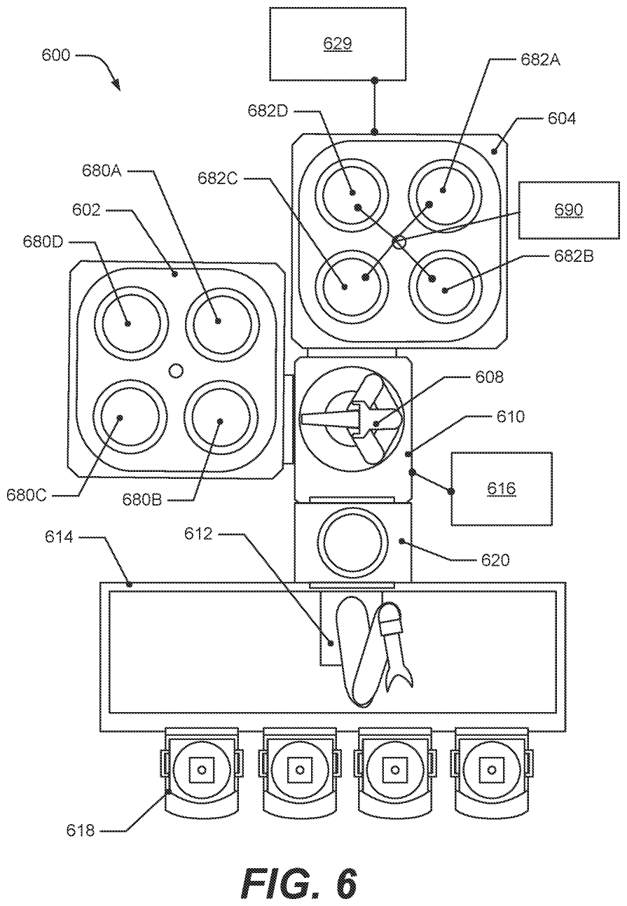

In some embodiments, instructions for a controller 550 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for transporting a substrate into the process chamber. A second recipe phase may include instructions for setting a flow rate of a silicon-containing precursor, instructions for setting a flow rate of hydrogen, instructions for setting a flow rate of a carrier gas (such as argon, helium, neon, krypton, and xenon), instructions for setting the chamber pressure and the substrate temperature, and time delay instructions for the second recipe phase. A third recipe phase may include instructions for setting a flow rate of an inert and/or silicon-containing precursor gas, instructions for setting a flow rate of an oxygen-containing species, instructions for setting a frequency and power of an RF source, and time delay instructions for a second recipe phase. It will be appreciated that these recipe phases may be further subdivided and/or iterated in any suitable way within the scope of the disclosed embodiments. In some embodiments, the controller 550 may include any of the features described below with respect to system controller 629 of FIG. 6.

As described above, one or more process stations may be included in a multi-station processing tool. FIG. 6 depicts an example processing apparatus according to disclosed embodiments. Tool 600 includes a first processing chamber 602 and a second processing chamber 604. The first processing chamber 602 includes a plurality of processing stations, four stations 680A-D, that each may process a wafer. The first processing chamber 602 is configured to perform plasma treatment operations on the wafers. The second processing chamber 404 is configured to perform deposition on the wafer and may be considered a deposition chamber. The second processing chamber 604 also includes a plurality of processing stations, four stations 682A-D, that each may process a wafer. The first and second processing chambers 602 and 604 may be considered multi-station processing chambers.

Tool 600 also includes a wafer transfer unit configured to transport one or more wafers within the tool 600. Additional features of tool 600 will be discussed in greater detail below, and various features are discussed here with respect to some of the described techniques. In the depicted illustration, the wafer transfer unit includes a first robotic arm unit 608 in a first wafer transfer module 610 and a second robotic arm unit 612 in a second wafer transfer module 614 that may be considered an equipment front end module (EFEM) configured to received containers for wafers, such as a front opening unified pod (FOUP) 616. The first robotic arm unit 608 is configured to transport a wafer between the first processing chamber 602 and the second processing chamber 604, and between the second the second robotic arm unit 612. The second robotic arm unit 612 is configured to transport the wafer between a FOUP and the first robotic arm unit 608. After a wafer has been treated in the first processing chamber 602, the wafer transfer unit is able to transfer the wafer from the first processing chamber 602, to the second processing chamber 604 where one or more layers of encapsulation material may be deposited on one or more wafers.

Similar to above, the first wafer transfer module 610 may a vacuum transfer module (VTM). Airlock 620, also known as a loadlock, is shown and may be individually optimized to perform various fabrication processes. The tool 600 also includes a FOUP 616 that is configured to lower the pressure of the tool 600 to a vacuum or low pressure, e.g., between about 1 mTorr and about 10 Torr, and maintain the tool 600 at this pressure. This includes maintaining the first and second processing chambers 602 and 604, and the first wafer transfer module 610 at the vacuum or low pressure. The second wafer transfer module 614 may be at a different pressure, such as atmospheric. As the wafer is transferred throughout the tool 600, it is therefore maintained at the vacuum or low pressure. For example, as the wafer is transferred from the first processing chamber 602, into the first wafer transfer module 610, and to the second processing chamber 604, the wafer is maintained at the vacuum or low pressure and not exposed to atmospheric pressure.

In a further example, a substrate is placed in one of the FOUPs 618 and the second robot arm unit 612, or front-end robot, transfers the substrate from the FOUP 618 to an aligner, which allows the substrate to be properly centered before it is etched, or deposited upon, or otherwise processed. After being aligned, the substrate is moved by the second robot arm unit 612 into the airlock 620. Because airlock modules have the ability to match the environment between an ATM and a VTM, the substrate is able to move between the two pressure environments without being damaged. From the airlock 620, the substrate is moved by the first robot arm unit 608 through the first wafer transfer module 610, or VTM 610, and into the first processing chamber 602. In order to achieve this substrate movement, the first robot arm unit 608 uses end effectors on each of its arms.

FIG. 6 also depicts an embodiment of a system controller 629 employed to control process conditions and hardware states of tool 600. System controller 629 may include one or more memory devices (not shown), one or more mass storage devices (not shown), and one or more processors (not shown). Processors may include a CPU or computer, analog, and/or digital input/output connections, stepper motor controller boards, etc.

In some embodiments, system controller 629 controls all of the activities of tool 600. System controller 629 executes system control software stored in mass storage device, loaded into memory device, and executed on processor. Alternatively, the control logic may be hard coded in the system controller 629. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software may include instructions for controlling the timing, mixture of gases, gas flow rates, chamber and/or station pressure, chamber and/or station temperature, wafer temperature, target power levels, RF power levels, substrate pedestal, chuck and/or susceptor position, and parameters of a particular process performed by tool 600. System control software may be configured in any suitable way. For example, various process tool component subroutines or control objects may be written to control operation of the process tool components used to carry out various process tool processes. System control software may be coded in any suitable computer readable programming language.

In some embodiments, system control software may include input/output control (IOC) sequencing instructions for controlling the various parameters described above. Other computer software and/or programs stored on mass storage device and/or memory device associated with system controller 629 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal and to control the spacing between the substrate and other parts of tool 600.

A process gas control program may include code for controlling gas composition (e.g., silicon-containing precursor gases, nitrogen-containing species, carrier gases, inert gases, and/or purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium or nitrogen) to the substrate.

A plasma control program may include code for setting RF power levels applied to the process electrodes in one or more process stations in accordance with the embodiments herein.

A pressure control program may include code for maintaining the pressure in the process chamber in accordance with the embodiments herein.

In some embodiments, there may be a user interface associated with system controller 429. The user interface may include a display screen, graphical software displays of the apparatus and/or process conditions, and user input devices such as pointing devices, keyboards, touch screens, microphones, etc.

In some embodiments, parameters adjusted by system controller 429 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 629 from various process tool sensors. The signals for controlling the process may be output on the analog and digital output connections of tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 629 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 629 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 629.

In some implementations, the system controller 629 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 629, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 629 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 629 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 629, in some implementations, may be a part of or coupled to a computer that is integrated with, coupled to the system, otherwise networked to the system, or a combination thereof. For example, the system controller 629 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the system controller 629 receives instructions in the form of data, which specify parameters for each of the processing steps to be performed during one or more operations. It should be understood that the parameters may be specific to the type of process to be performed and the type of tool that the system controller 629 is configured to interface with or control. Thus, as described above, the system controller 629 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 629 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

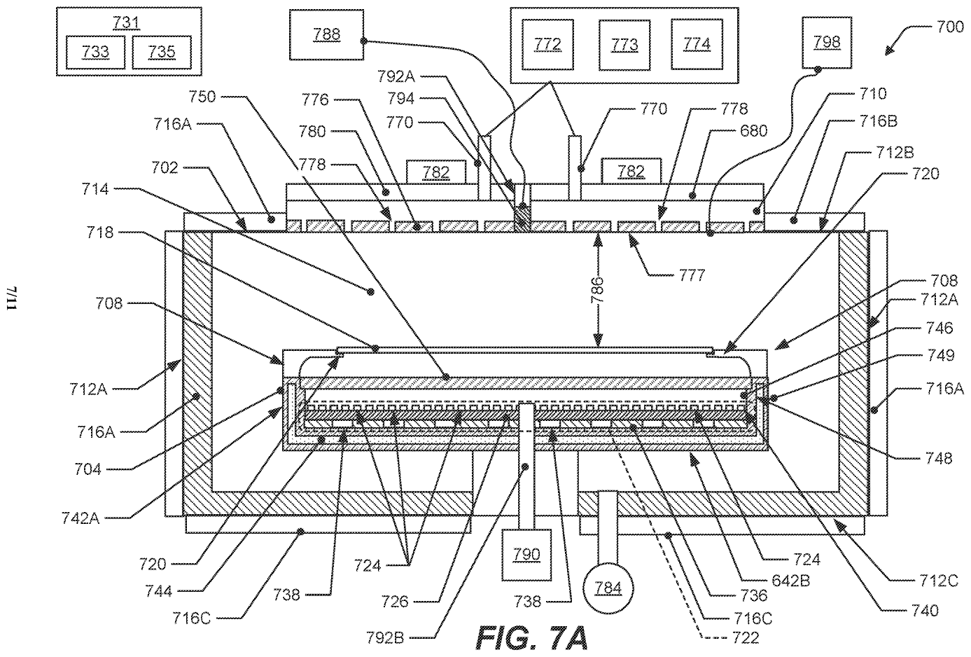

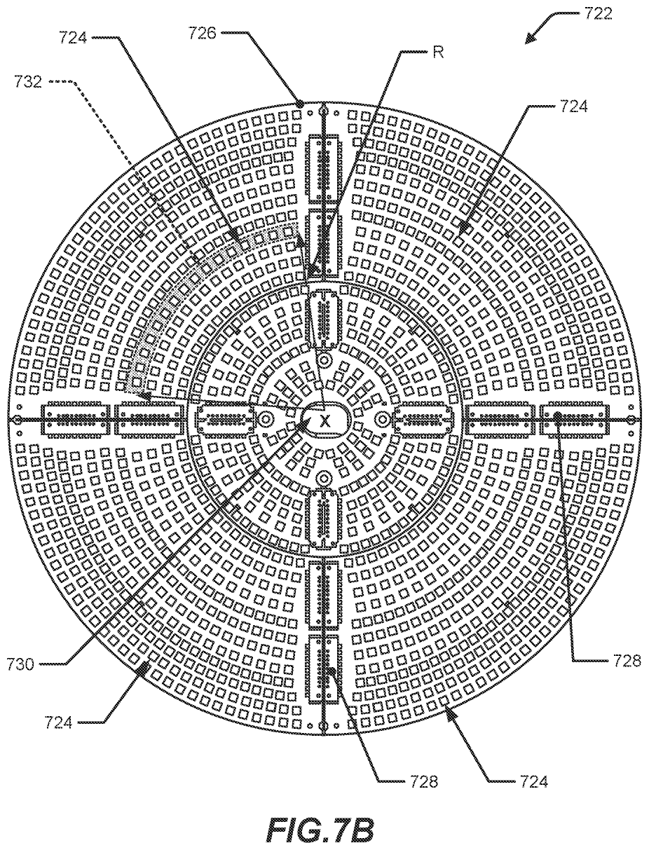

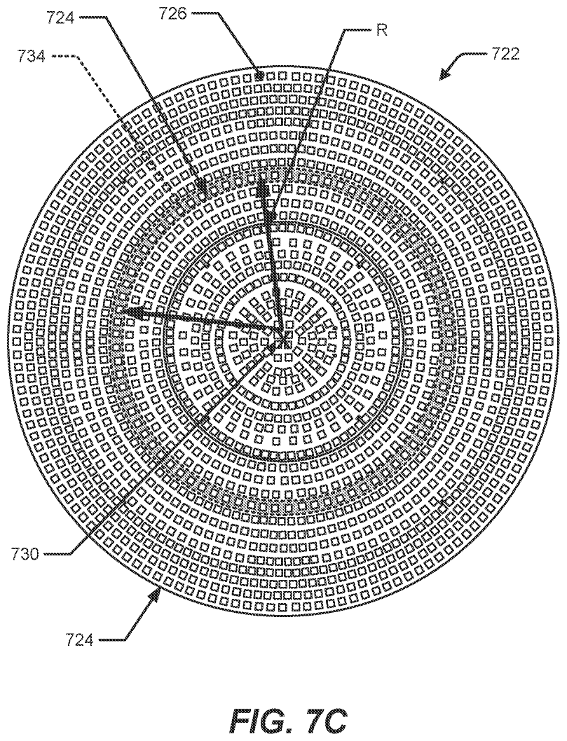

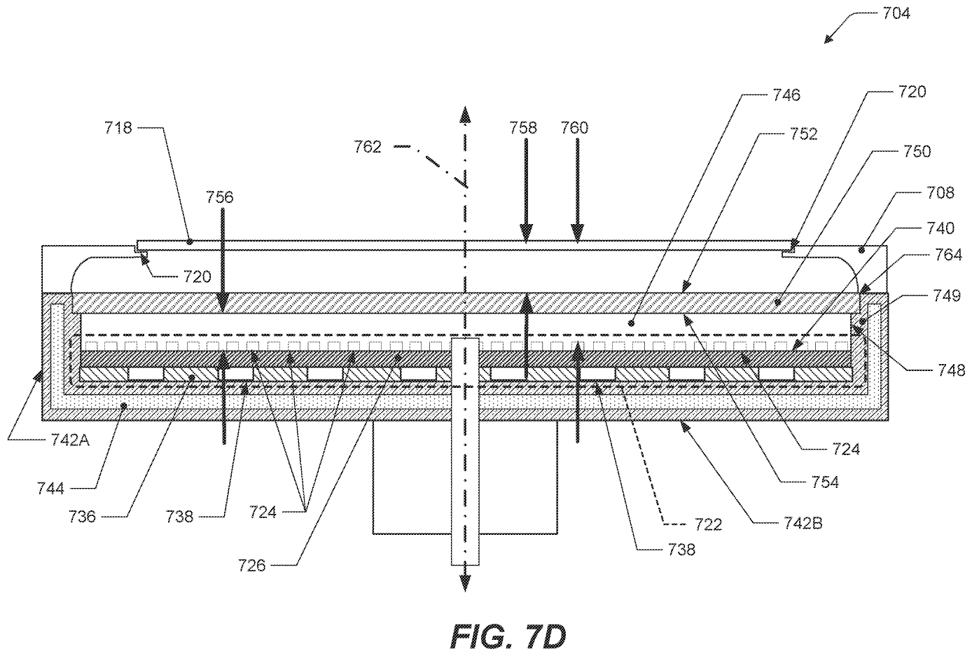

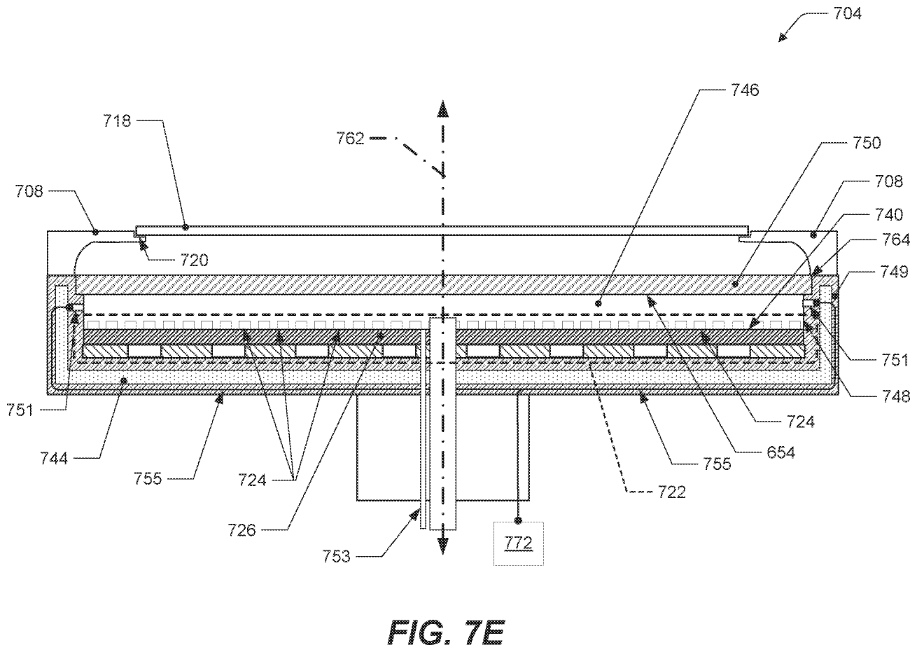

FIG. 7A depicts a cross-sectional side view of an example apparatus in accordance with some embodiments. As detailed below, this apparatus 700 is capable of rapidly and precisely controlling the temperature of a substrate, including performing thermal atomic layer etching (ALE) operations, an example of which is a Prevos™ selective Etch Tool, produced by Lam Research Corporation of Fremont, California.

The apparatus 700 includes a processing chamber 702, a pedestal 704 having a plurality of substrate supports 708 configured to support a substrate 718, and a gas distribution unit 710. The processing chamber 702 includes sides walls 712A, a top 712B, and a bottom 712C, that at least partially define the chamber interior 714, which may be considered a plenum volume. As stated herein, it may be desirable in some embodiments to actively control the temperature of the processing chamber walls 712A, top 712B, and bottom 712C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 712A, the top 712B, and the bottom 712C. As illustrated in FIG. 7A, chamber heaters 716A are positioned on and configured to heat the chamber walls 712A, chamber heaters 716B are positioned on and configured to heat the top 712B, and chamber heaters 716C are positioned on and configured to heat the bottom 712C. The chamber heaters 716A-716C may be resistive heaters that are configured to generate heat when an electrical current is flowed through a resistive element. Chamber heaters 716A-716C may also be fluid conduits through which a heat transfer fluid may be flowed, such as a heating fluid which may include heated water. In some instances, the chamber heaters 716A-716C may be a combination of both heating fluid and resistive heaters. The chamber heaters 716A-716C are configured to generate heat in order to cause the interior surfaces of each of the chamber walls 712A, the top 712B, and the bottom 712C to the desired temperature, which may range about 40 to about 400° C., or about 40 to about 250° C., or about 40 to about 150° C., or about 80 to about 130° C., or about 90 to about 120° C., for instance. It has been discovered that under some conditions, water and alcohol vapors do not condense on surfaces kept at about 90° C. or higher. While not shown in FIG. 7A, chamber heaters 716A-716C may include one or more temperature sensors operably coupled to the chamber heaters 716A-716C to monitor the chamber temperature.

The chamber walls 712A, top 712B, and bottom 712C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances, the materials of the coatings may be blended or layers of differing material combinations, such as alternating layers of aluminum oxide and yttria, or aluminum oxide and zirconia. These materials are configured to withstand the chemistries used in the processing techniques, such as anhydrous HF, water vapor, methanol, isopropyl alcohol, chlorine, fluorine gases, nitrogen gas, hydrogen gas, helium gas, and mixtures thereof.

The apparatus 700 may also be configured to perform processing operations at or near a vacuum, such as at a pressure of about 0.1 Torr to about 100 Torr, or about 20 Torr to about 200 Torr, or about 0.1 Torr to about 10 Torr, or about 1 to about 20 Torr, or about 0.5 to about 5 Torr. This may include a vacuum pump 784 configured to pump the chamber interior 714 to low pressures, such as a vacuum having a pressure of about 0.1 Torr to about 100 Torr, including about 0.1 Torr to about 10 Torr, and about 20 Torr to about 200 Torr, or about 0.1 Torr to about 10 Torr, or about 1 to about 20 Torr, or about 0.5 to about 5 Torr.

Various features of the pedestal 704 will now be discussed. The pedestal 704 includes a heater 722 (encompassed by the dashed rectangle in FIG. 7A) that has a plurality of LEDs 724 that are configured to emit visible light having wavelengths including and about 400 to about 800 nm, including 450 nm. The heater LEDs emit this visible light onto the backside of the substrate which heats the substrate. Visible light having wavelengths about 400 to about 800 nm is able to heat silicon substrates quickly and efficiently from ambient temperature, e.g., about 20° C., to temperatures as high as about 600° C. because silicon absorbs visible light within this range. In contrast, radiant heating, including infrared radiant heating, may ineffectively heat silicon at temperatures up to about 400° C. because silicon tends to be transparent to infrared at temperatures lower than about 400° C. Additionally, radiant heaters that directly heat the topside of a substrate, as in many conventional semiconductor processes, can cause damage or other adverse effects to the topside films. Many “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat some pedestals to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip may have three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, twelve, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

FIG. 7B depicts a top view of a substrate heater with a plurality LEDs. This substrate heater 722 includes a printed circuit board 726 and the plurality of LEDs 724, some of which are labeled; this depicted plurality includes approximately 1,300 LEDs. External connections 728 are connected by traces to provide power to the plurality of LEDs 724. As illustrated in FIG. 7B, the LEDs may be arranged along numerous arcs that are radially offset from the center 730 of the substrate heater 722 by different radiuses; in each arc, the LEDs may be equally spaced from each other. For example, one arc 732 is surrounded by a partially shaded dotted shape, includes 16 LEDs 724, and is a part of a circle with a radius R that extends around the center 730. The 16 LEDs 724 may be considered equally spaced from each other along this arc 732.

In some embodiments, the LEDs may also be arranged along circles around the center of the substrate heater. In some instances, some LEDs may be arranged along circles while others may be arranged along arcs. FIG. 7C depicts a top view of another example of a substrate heater with a plurality LEDs. The substrate heater 722 of FIG. 7C includes a printed circuit board 726 and the plurality of LEDs 724, some of which are labeled. Here, LEDs 724 are arranged along numerous circles that are radially offset from the center 730 of the substrate heater 722 by different radiuses; in each circle, the LEDs may be equally spaced from each other. For example, one circle 734 is surrounded by a partially shaded ring, includes 78 LEDs 724, and has a radius R that extends around the center 730. The 78 LEDs 724 may be considered equally spaced from each other along this circle 734. The arrangement of the LEDs in FIG. 7C may provide a more uniform light and heat distribution pattern across the entire backside of the substrate compared to the arrangement in FIG. 7B because the regions of the substrate heater 722 in FIG. 7B that contain the external connections may provide unheated cold spots on the substrate, especially because the substrate and heater remain stationary with respect to each other during processing; the substrate and the substrate heater do not rotate.

In some embodiments, the plurality of LEDs may include at least about 1,000 LEDs, including about 1,200, 1,500, 2,000, 3,000, 4,000, 5,000, or more than 6,000, for instance. Each LED may, in some instances, be configured to uses about 4 watts or less at 100% power, including about 3 watts at 100% power and about 1 watt at 100% power. These LEDs may be arranged and electrically connected into individually controllable zones to enable temperature adjustment and fine tuning across the substrate. In some instances, the LEDs may be grouped into at least 20, for instance, independently controllable zones, including at least about 25, 50, 75, 80, 85 90, 95, or 100 zones, for instance. These zones may allow for temperature adjustments in the radial and azimuthal (i.e., angular) directions. These zones can be arranged in a defined pattern, such as a rectangular grid, a hexagonal grid, or other suitable pattern for generating a temperature profile as desired. The zones may also have varying shapes, such as square, trapezoidal, rectangular, triangular, obround, elliptical, circular, annular (e.g., a ring), partially annular (e.g., an annular sector), an arc, a segment, and a sector that may be centered on the center of the heater and have a radius less than or equal to the overall radius of the substrate heater's PCB. For example, in FIG. 7B the LEDs have 88 zones that are organized into at least 20, such as 20 or 21, concentric rings. These zones are able to adjust the temperature at numerous locations across the substrate in order to create a more even temperature distribution as well as desired temperature profiles, such as higher temperatures around the edge of the substrate than in the center of the substrate. The independent control of these zones may also include the ability to control the power output of each zone. For example, each zone may have at least 15, 20, or 25 adjustable power outputs. In some instances, each zone may have one LED thereby enabling each LED to be individually controlled and adjusted which can lead to a more uniform heating profile on the substrate. Accordingly, in some embodiments, each LED of the plurality of LEDs in the substrate heater may be individually controllable.

In certain embodiments, the substrate heater 722 is configured to heat the substrate to multiple temperatures and maintain each such temperature for various durations. The substrate heater may be configured to heat the substrate to between about 50 to about 700° C., including to any temperature or range between these temperatures. Additionally, in some embodiments, the substrate heater 722 is configured to heat the substrate to any temperature within these ranges in less than about 60 seconds, less than about 45 seconds, less than about 30 seconds, or less than about 15 seconds, for instance. In certain embodiments, the substrate heater 722 is configured to heat a substrate at one or more heating rates, such as between at least about 0.1° C./second and at least about 20° C./second, for example.

The substrate heater may increase the temperature of the substrate by causing the LEDs to emit the visible light at one or more power levels, including at least about 80%, at least about 90%, at least about 95%, or at least about 100% power. In some embodiments, the substrate heater is configured to emit light about 10 to about 4000 W, including at least about 10 W, at least about 30 W, at least about 0.3 kilowatt (kW), at least about 0.5 kW, at least about 2 kW, at least about 3 kW, or at least about 4 kw. The apparatus is configured to supply about 0.1 to about 9 kW of power to the pedestal; the power supply is connected to the substrate heater through the pedestal but is not depicted in the Figures. During temperature ramps, the substrate heater may operate at the high powers, and may operate at the lower power levels (e.g., including about 5 W to about 0.5 kW) to maintain the temperature of a heated substrate.

The pedestal may include reflective material on its internal surfaces that, during operation, reflects and directs the light emitted by the LEDs onto the backside of the substrate supported by the pedestal. In some such embodiments, the substrate heater may include such reflective material positioned on a top surface 740, as shown in FIG. 7A, of the PCB 726 on which the plurality of LEDs 724 is positioned. The reflective material may be comprised of aluminum, such as polished aluminum, stainless steel, aluminum alloys, nickel alloys, and other protective layers which can prevent oxidation of the metal and/or enhance the reflectivity at specific wavelengths, such as reaching greater than 99% reflectivity for specific wavelengths, and other durable reflective coatings. Additionally or alternatively, the pedestal 704 may have a bowl 746 in which the substrate heater 722 is at least partially positioned. The bowl 746 may have exposed internal surfaces 748 of the pedestal sidewalls 749 upon which the reflective material may be positioned. This reflective material increases the heating efficiency of the substrate heater and reduces the unwanted heating of the PCB 726 and pedestal 704 by advantageously directing light back onto the substrate that would have otherwise been absorbed by the PCB 726 and the pedestal 704.

In some embodiments, the substrate heater may also include a pedestal cooler that is thermally connected to the LEDs such that heat generated by the plurality of LEDs can be transferred from the LEDs to the pedestal cooler. This thermal connection is such that heat can be conducted from the plurality of LEDs to the pedestal cooler along one or more heat flow pathways between these components. In some instances, the pedestal cooler is in direct contact with one or more elements of the substrate heater, while in other instances other conductive elements, such as thermally conductive plates (e.g., that comprise a metal) are interposed between the substrate heater and the pedestal cooler. Referring back to FIG. 7A, the substrate heater includes a pedestal cooler 736 in direct contact with the bottom of the PCB 726. Heat is configured to flow from the LEDs, to the PCB 726, and to the pedestal cooler 736. The pedestal cooler 736 also includes a plurality of fluid conduits 738 through which a heat transfer fluid, such as water, is configured to flow in order to receive the heat and thus cool the LEDs in the substrate heater 722. The fluid conduits 738 may be connected to a reservoir and pump, not pictured, located outside the chamber. In some instances, the pedestal cooler may be configured to flow water that is cooled, such as about 5 to about 20° C.

As provided herein, it may be advantageous to actively heat the exterior surfaces of the processing chamber 702. In some instances, it may similarly be advantageous to heat the exterior surfaces of the pedestal 704 in order to prevent unwanted condensation and deposition on its external surfaces. As illustrated in FIG. 7A, the pedestal 704 may further include a pedestal heater 744 inside of the pedestal 704 that is configured to heat the exterior surfaces of the pedestal 704, including its sides 742A and bottom 742B. The pedestal heater 744 may include one or more heating elements, such as one or more resistive heating elements and fluid conduits in which a heating fluid is configured to flow. In some instances, the pedestal cooler and the pedestal heater may both have fluid conduits that are fluidically connected to each other such that the same heat transfer fluid may flow in both the pedestal cooler and the pedestal heater. In these embodiments, the fluid may be heated to about 50 to about 130° C. including about 90 to about 120° C.

The pedestal may also include a window to protect the substrate heater, including the plurality of LEDs, from damage caused by exposure to the processing chemistries and pressures used during processing operations. As illustrated in FIG. 7A, the window 750 may be positioned above the substrate heater 722 and may be sealed to the sidewall 749 of the pedestal 704 in order to create a plenum volume within the pedestal that is fluidically isolated from the chamber interior. This plenum volume may also be considered the inside of the bowl 746. The window may be comprised of one or more materials that are optically transparent to the visible light emitted by LEDs, including light having wavelengths in the range of 400 nm to 800 nm. In some embodiments, this material may be quartz, sapphire, quartz with a sapphire coating, or calcium fluoride (CaF). The window may also not have any boles or openings within it. In some embodiments, the heater may have a thickness of about 15 to 30 mm, including about 20 mm and about 25 mm.

FIG. 7D depicts the pedestal of FIG. 7A with additional features in accordance with various embodiments. As identified in FIG. 7D, the window 750 includes a top surface 752 that faces the substrate 718 supported by the pedestal 704, and a bottom surface 754 that faces the substrate heater 722. In some embodiments, the top and the bottom surfaces 752 and 754 may be flat, planar surfaces (or substantially flat, e.g., within ±10% or 5% of flat). In some other instances, the top 752, bottom 754, or both top 752 and bottom 754 may be nonplanar surfaces. The nonplanarity of these surfaces may be configured to refract and/or direct the light emitted by the substrate heater 722's LEDs 724 to more efficiently and/or effectively heat the substrate. The nonplanarity may also be along some or all of the surface. For example, the entire bottom surface may have a convex or concave curvature, while in another example an outer annular region of the bottom surface may have a convex or concave curvature while the remaining portion of the surface is planar. In further examples, these surfaces may have multiple, but different, nonplanar sections, such as having a conical section in the center of the surface that is adjacent to a planar annular section, that is adjacent to a conical frustum surface at the same or different angle as the conical section. In some embodiments, the window 750 may have features that act as an array of lenses which are oriented to focus the light emitted by one or more LEDs, such as each LED.

With the window 750 positioned above the substrate heater 722, the window 750 gets heated by the substrate heater 722 which can affect the thermal environment around the substrate. Depending on the material or materials used for the window 750, such as quartz, the window may retain heat and progressively retain more heat over the course of processing one or more substrates. This heat can get radiatively transferred to the substrate and therefore directly heat the substrate. In some instances, that the window can cause a temperature increase of between 50° C. and 80° C. above the heater temperature. This heat may also create a temperature gradient through the thickness, or in the vertical direction, of the window. In some instances, the top surface 752 is 30° C. hotter than the bottom surface 754. It may therefore be advantageous to adjust and configure the chamber to account for and reduce the thermal effects of the window. This may include detecting the substrate's temperature and adjusting the substrate heater to account for the heat retained by the window.

This may also include various configurations of the pedestal, such as actively cooling the window. In some embodiments, like that shown in FIGS. 7A and 7D, the window 750 may be offset from the substrate heater 722 by a first distance 756. In some embodiments, this first distance may be about 2 to about 50 mm, including about 5 to about 40 mm. A cooling fluid, such as an inert gas, may be flowed between the window 750 and the substrate heater 722 in order to cool both the window 750 and the substrate heater 722. The pedestal may have one or more inlets and one or more outlets for flowing this gas within the plenum volume, or bowl 746, of the pedestal 704. The one or more inlets are fluidically connected to the inert gas source outside the processing chamber 702, which may include through fluid conduits that may be at least partially routed inside the pedestal 704. The one or more outlets are fluidically connected to an exhaust or other environment outside the processing chamber 702, which may also be through fluid conduits running within the pedestal. In FIG. 7E, which depicts the pedestal of FIG. 7D with additional features in accordance with various embodiments, one or more inlets 751 are positioned in the sidewalls 749 and extend through the internal surface 748; the one or more inlets are also fluidically connected to a gas source 772 (e.g., an inert gas source) through, in part, fluid conduits 755 that are routed through the pedestal 704. A single outlet 753 is positioned in a center region, i.e., not in the exact center but in close proximity, of the substrate heater 722. In some embodiments, the one or more gas inlets and one or more outlets may be switched, such that the one or more outlets extend through the sidewalls 749 (i.e., they are items 751 in FIG. 7E), and the one or more inlets may be the center region of the substrate heater 722 (i.e., they are item 753 in FIG. 7E). In some embodiments, there may be more than one outlet; in some embodiments, there may only be a single gas inlet. In some embodiments, one or more gas inlets extend through the internal surface 748 of the pedestal sidewall 749 underneath the LED heater 722 and one or more gas outlets extend through another part of the pedestal sidewall 749, such as a mounting bracket between the LED heater 722 and the pedestal sidewall 749.

In some embodiments, the window may be placed in direct, thermal contact with the substrate heater and the pedestal cooler may be configured to cool both the PCB and the window. In some embodiments, as also shown in FIGS. 7A and 7D, the window 750 may be thermally connected to the sidewalls 749 of the pedestal 704 in order to transfer some of the retained heat in the window 750 to the pedestal 704. This transferred heat may be further transferred out of the pedestal using, for instance, the pedestal heater 744 which may flow fluid through the pedestal 704 that is heated to about 20 to about 100° C., for instance. This heated fluid may be cooler than the temperature of the pedestal 704 at the thermal connection with the window 750. In some embodiments, the window 750 may have one or more fluid conduits within the window 750 through which transparent cooling fluid may be configured to flow. The fluid may be routed to the window through the pedestal from a fluid source or reservoir outside the chamber.

As shown in FIGS. 7A and 7D, the pedestal's 704 substrate supports 708 are configured to support the substrate 718 above and offset from the window 750 and the substrate heater 722. In certain embodiments, the temperature of the substrate can be rapidly and precisely controlled by thermally floating, or thermally isolating, the substrate within the chamber. It is desirable to position the substrate so that the smallest thermal mass is heated and cooled. This thermal floating is configured to position the substrate so that it has minimal thermal contact (which includes direct and radiation) with other bodies in the chamber.

The pedestal 704 is therefore configured, in some embodiments, to support the substrate 718 by thermally floating, or thermally isolating, the substrate within the chamber interior 714. The pedestal's 704 plurality of substrate supports 708 are configured to support the substrate 718 such that the thermal mass of the substrate 718 is reduced as much as possible to the thermal mass of just the substrate 718. Each substrate support 708 may have a substrate support surface 720 that provides minimal contact with the substrate 718. The number of substrate supports 708 may range from at least 3 to, for example, at least 6 or more. The surface area of the support surfaces 720 may also be the minimum area required to adequately support the substrate during processing operations (e.g., in order to support the weight of the substrate and prevent inelastic deformation of the substrate).

The substrate supports are also configured to prevent the substrate from being in contact with other elements of the pedestal, including the pedestal's surfaces and features underneath the substrate. As seen in FIGS. 7A and 7D, the substrate supports 708 hold the substrate 718 above and offset from the next adjacent surface of the pedestal 704 below the substrate 718, which is the top surface 752 (identified in FIG. 7D) of the window 750. As can be seen in FIG. 7A, a volume or gap exists underneath the substrate, except for the contact with the substrate supports. As illustrated in FIG. 7D, the substrate 718 is offset from the top surface 752 of the window 750 by a distance 758. This distance 758 may affect the thermal effects caused by the window 750 to the substrate 718. The larger the distance 758, the less the effects. It was found that a distance 758 of 2 mm or less resulted in a significant thermal coupling between the window and the substrate; it is therefore desirable to have a larger distance 758 than 2 mm, such as at least about 5 mm, about 10 mm, about 15 mm, about 20 mm, about 30 mm, about 50 mm, or about 100 mm, for example.

The substrate 718 is also offset from the substrate heater 722 (as measured in some instances from a top surface of the substrate heater 722 which may be the top surface of the LEDs 724) by a distance 760. This distance 760 affects numerous aspects of heating the substrate 718. In some embodiments, a distance 760 of about 10 to about 90 mm, or about 5 to about 100 mm, or about 10 to about 30 mm, for instance, provides a substantially uniform heating pattern and acceptable heating efficiency.

As stated, the substrate supports 708 are configured to support the substrate 718 above the window. In some embodiments, these substrate supports are stationary and fixed in position; they are not lift pins or a support ring. In some embodiments, at least a part of each substrate support 708 that includes the support surface 720 may be comprised of a material that is transparent at least to light emitted by LEDS 724. This material may be, in some instances, quartz or sapphire. The transparency of these substrate supports 708 may enable the visible light emitted by the LEDs 724 in the substrate heater 722 to pass through the substrate support 708 and to the substrate 718 so that the substrate support 708 does not block this light and the substrate 718 can be heated in the areas where it is supported. This may provide a more uniform heating of the substrate 718 than with a substrate support comprising a material opaque to visible light. In some other embodiments, the substrate supports 708 may be comprised of a non-transparent material, such as zirconium dioxide (ZrO₂).

In some embodiments, the pedestal may be constructed to directly support a substrate (not shown). The pedestal may be configured with lift pins or other movable support members to position a substrate within a deposition zone in an environment of the substrate. A substrate may be moved in a vertical direction within a chamber. In some embodiments, the pedestal includes an electrostatic chuck. The electrostatic chuck may be an uppermost part of the pedestal, and may include one or more electrostatic clamping electrodes embedded within a body of the electrostatic chuck. The substrate may be supported on the top surface of the electrostatic chuck. In some embodiments, the one or more electrostatic clamping electrodes may be coplanar or substantially coplanar. The electrostatic clamping electrodes may be powered by a DC power source or DC chucking voltage (e.g., about 200 to about 2000 V) so that the substrate may be retained on the electrostatic chuck by electrostatic attractive forces. Power to the electrostatic clamping electrodes may be provided via first electrical lines that is connected to the electrostatic clamping electrodes. The electrostatic chuck may further include one or more heating elements embedded within the body of the electrostatic chuck. The one or more heating elements may include resistive heaters. In some embodiments, the one or more heating elements are positioned below the one or more electrostatic clamping electrodes. The one or more heating elements may be configured to heat the substrate to a temperature greater than about 200° C., greater than about 450° C., greater than about 500° C., greater than about 550° C., greater than about 600° C., greater than about 650° C., or greater than about 700° C. The one or more heating elements provide selective temperature control to the substrate. Power to the one or more heating elements may be provided via second electrical lines connecting the one or more heating elements and a power source.

In some embodiments, such as those shown in FIG. 7D, the substrate supports 708 may be positioned closer to a center axis 762 of the window than the outer diameter 764 of the window 750. In some instances, portions of these substrate support may extend over and above the window 750.

Referring back to FIG. 7A, in some embodiments, the pedestal is also configured to move vertically. This may include moving the pedestal such that a gap 786 between a faceplate 776 of the gas distribution unit 710 and the substrate 718 is capable of being in a range about 2 to about 70 mm. Moving the pedestal vertically may enable active cooling of the substrate as well as rapid cycling time of processing operations, including flowing gas, and purging, due to a low volume created between the gas distribution unit 710 and the substrate 718. This movement may also enable the creation of a small process volume between the substrate and the gas distribution unit which can result in a smaller purge and process volumes and thus reduce purge and gas movement times and increase throughput.

The gas distribution unit 710 is configured to flow process gases, which may include liquids and/or gases, such as a reactant, modifying molecules, converting molecules, or removal molecules, onto the substrate 718 in the chamber interior 714. The gas distribution unit 710 may be configured to atomize liquid at an atmospheric temperature into a fine droplet in the chamber interior 714. In some embodiments, the process gas may include (diluted) hydrogen fluoride (HF), oxygen, ozone, hydrogen peroxide, or combination thereof. As seen in FIG. 7A, the gas distribution unit 710 includes one or more fluid inlets 770 that are fluidically connected to one or more gas sources 772 and/or one or more vapor sources 774. The gas distribution unit 710 and other units or parts that may be fluidly in contact with the process gases may be designed and fabricated to be chemically resistant or chemically inert to the process gases. In some embodiments, the gas lines and mixing chamber may be heated to prevent unwanted condensation of the vapors and gases flowing within. These lines may be heated to at least about 40° C., at least about 80° C., at least about 90° C., at least about 120° C., at least about 130° C., or at least about 150° C. The one or more vapor sources may include one or more sources of gas and/or liquid which is vaporized. The vaporizing may be a direct inject vaporizer, a flow over vaporizer, or both. In some embodiments, one or more vapor sources and one or more process gases may be configured to operate either sequentially or concurrently. The gas distribution unit 710 also includes the faceplate 776 that includes a plurality of through-holes 778 that fluidically connect the gas distribution unit 710 with the chamber interior 714. These through-holes 778 are fluidically connected to the one or more fluid inlets 770 and also extend through a front surface 777 of the faceplate 776, with the front surface 777 configured to face the substrate 718. In some embodiments, the gas distribution unit 710 may be considered a top plate and in some other embodiments, it may be considered a showerhead.

The through-holes 778 may be configured in various ways in order to deliver uniform gas flow onto the substrate. In some embodiments, these through-holes may all have the same outer diameter, such as about 0.03 to about 0.05 inches, including about 0.04 inches (1.016 mm). These faceplate through-holes may also be arranged throughout the faceplate in order to create uniform flow out of the faceplate.

Referring back to FIG. 7A, the gas distribution unit 710 may also include a unit heater 780 that is thermally connected to the faceplate 776 such that heat can be transferred between the faceplate 776 and the unit heater 780. The unit heater 780 may include fluid conduits in which a heat transfer fluid may be flowed. Similar to above, the heat transfer fluid may be heated to a temperature range of about 20° C. and 120° C., for example. In some instances, the unit heater 780 may be used to heat the gas distribution unit 710 to prevent unwanted condensation of vapors and gases; in some such instances, this temperature may be at least about 90° C. or 120° C.

In some embodiments, the gas distribution unit 710 may include a second unit heater 782 that is configured to heat the faceplate 776. This second unit heater 782 may include one or more resistive heating elements, fluid conduits for flowing a heating fluid, or both. Using two unit heaters 780 and 782 in the gas distribution unit 710 may enable various heat transfers within the gas distribution unit 710. This may include using the first and/or second unit heaters 780 and 782 to heat the faceplate 776 in order to provide a temperature-controlled chamber, as described above, in order to reduce or prevent unwanted condensation on elements of the gas distribution unit 710.

The apparatus 700 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 780 that flows the heat transfer fluid through fluid conduits may be used to cool the substrate 718 by transferring heat away from the faceplate 776 that is transferred from the substrate 718. A substrate 718 may therefore be cooled by positioning it in close proximity to the faceplate 776, such as by a gap 786 of less than or equal to 5 mm or 2 mm, such that the heat in the substrate 718 is radiatively transferred to the faceplate 776, and transferred away from the faceplate 776 by the heat transfer fluid in the first unit heater 780. The faceplate 776 may therefore be considered a heat sink for the substrate 718 in order to cool the substrate 718.

In some embodiments, the apparatus 700 may further include a cooling fluid source 773, which may contain a cooling fluid (a gas or a liquid), and a cooler (not pictured) configured to cool the cooling fluid to a desired temperature, such as less than or equal to about 90° C., less than or equal to about 70° C., less than or equal to about 50° C., less than or equal to about 20° C., less than or equal to about 10° C., less than or equal to about 0° C. less than or equal to about −50° C., less than or equal to about −100° C., less than or equal to about −150° C., less than or equal to about −190° C., about −200° C., or less than or equal to about −250° C., for instance. The apparatus 200 includes piping to deliver the cooling fluid to the one or more fluid inlets 770, and the gas distribution unit 710 which is configured to flow the cooling fluid onto the substrate. In some embodiments, the fluid may be in liquid state when it is flowed to the processing chamber 702 and may turn to a vapor state when it reaches the chamber interior 714, for example if the chamber interior 714 is at a low pressure state, such as described above, e.g., about 0.1 to about 10 Torr, or about 0.1 to about 100 Torr, or about 20 to about 200 Torr, for instance. The cooling fluid may be an inert element, such as nitrogen, argon, or helium. In some instances, the cooling fluid may include, or may only have, a non-inert element or mixture, such as hydrogen gas. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

In some embodiments, the apparatus 700 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used.

In some embodiments, the apparatus 700 may include a mixing plenum for blending and/or conditioning process gases for delivery before reaching the fluid inlets 770. One or more mixing plenum inlet valves may control introduction of process gases to the mixing plenum. In some other embodiments, the gas distribution unit 210 may include one or more mixing plenums within the gas distribution unit 710. The gas distribution unit 710 may also include one or more annular flow paths fluidically connected to the through-holes 778 which may equally distribute the received fluid to the through-holes 778 in order to provide uniform flow onto the substrate.

The apparatus 700 may also include one or more additional non-contact sensors for detecting the temperature of the substrate. Such sensors may include improved pyrometers, for instance. Although conventional pyrometers are not able to detect certain substrates within particular temperature ranges, the pyrometer described herein overcomes these problems. For instance, the pyrometer is configured to detect multiple emission ranges in order to detect multiple types of substrates, e.g., doped, low doped, or not doped, at various temperature ranges. This includes a configuration to detect emission ranges of about 0.95 microns to about 1.1 microns, about 1 micron, about 1 to about 4 microns, and/or about 8 to 15 microns. The pyrometer is also configured to detect the temperature of a substrate at a shorter wavelength in order to differentiate the signal from the thermal noise of the chamber.

The pyrometer may include an emitter configured to emit infrared signals and a detector configured to receive emissions. Referring to FIG. 7A, the apparatus includes the pyrometer 788 having an emitter within the pyrometer 788 and a detector 790. The pyrometer may be configured to emit signals on one side of the substrate, either the top or the bottom, and configured to receive signals on the other side of the substrate. For instance, the emitter may emit signals on the top of the substrate and the detector is under the substrate and receives signals emitted through and under the substrate. The apparatus may therefore have at least a first port 792A on the top of the processing chamber 702, such as the port 792A through the center of the gas distribution unit 710, and a second port 792B through the pedestal 704 and substrate heater 722. The emitter in the pyrometer 788 may be connected to one of the ports 792A or 792B via a fiberoptic connection, such as the first port 792A as shown in FIG. 7A, and the detector is optically connected to the other port, such as the second port 792B in FIG. 7A. The first port 792A may include a port window 794 to seal the first port 792A from the chemistries within the chamber interior 714. The second port 792B is seen in FIG. 7A extending through the pedestal 704 and the substrate heater such that the emitter's emissions can pass through the substrate, through the window 750, into the second port 792B and to the detector 790 that may be positioned in the second port or optically connected to the second port through another fiberoptic connection (not shown). In some other embodiments, the emitter and the detector are flipped, such that the emitter emits through the second port 792B and the detector detects through the first port 792A.

The apparatus 700 may also include one or more optical sensors 798 to detect one or more metrics of the visible light emitted by the LEDs. In some embodiments, these optical sensors may be one or more photodetectors configured to detect the light and/or light intensity of the light emitted by the LEDs of the substrate heater. In FIG. 7A, a single optical sensor 798 is shown as connected to the chamber interior 714 via fiberoptic connection such that the optical sensor 798 is able to detect light emitted by the substrate heater 722. The optical sensor 798, and additional optical sensors, can be positioned in various locations in the top and sides, for instance, of the processing chamber 702 in order to detect the emitted light at various locations within the processing chamber 702. As discussed below, this may enable the measurement and adjustment of the substrate heater, such as the adjustment of one or more independently controllable zones of the LEDs. In some embodiments, there may be a plurality of optical sensors 798 arranged along a circle or multiple concentric circles in order to measure various regions of the LEDs throughout the processing chamber 702. In some embodiments, the optical sensors may be positioned inside the chamber interior 714.

In some embodiments, the apparatuses described herein may include a controller that is configured to control various aspects of the apparatus in order to perform the techniques described herein. For example, referring back to FIG. 7A, apparatus 700 includes a controller 731 (which may include one or more physical or logical controllers) that is communicatively connected with and that controls some or all of the operations of a processing chamber. The system controller 731 may include one or more memory devices 733 and one or more processors 735. In some embodiments, the apparatus includes a switching system that is operably coupled to the system controller 731 for controlling flow rates and durations, the substrate heating unit, the substrate cooling unit, the loading and unloading of a substrate in the chamber, the thermal floating of the substrate, and the process gas unit, for instance, when disclosed embodiments are performed. For example, the switching system may control flow rates and durations of water vapor in the chamber such that one or more monolayers of water is controllably adsorbed on a substrate, or on the silicon nitride surface. In some embodiments, the apparatus may have a switching time of up to about 500 milliseconds (ms), or up to about 750 ms. Switching time may depend on the flow chemistry, recipe chosen, reactor architecture, and other factors.

In some embodiments, the switching system of the apparatus may be coupled to one or more contact or non-contact sensors to monitor the substrate temperature, one or more temperature sensors operably coupled to the chamber heaters to monitor the chamber temperature, or the gas distribution unit to monitor and control a flow rate and a duration of the one or more gaseous reactant and vapor.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, the apparatus/process described herein may be used in conduction with a CVD or PECVD chamber or module, an ALD or PEALD chamber or module, an atomic layer etch (ALE) chamber or module, a plasma etch chamber or module, and any other semiconductor processing systems that may be associated or used in the fabrication and/or manufacturing of semiconductor wafers, displays, LEDs, photovoltaic panels and the like. In some embodiments, example systems may include a combination of an ALD (thermal ALD) or PEALD chamber or module and an ALE chamber or module such that one or more depositions and oxidations are performed on a substrate followed by one or more etching without breaking a vacuum in the chamber or exposing the substrate to an ambient atmosphere.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

In some embodiments, the apparatus may further be configured to generate a plasma and use the plasma for some processing in various embodiments. This may include having a plasma source configured to generate a plasma within the chamber interior, such as a capacitively coupled plasma (CCP), an inductively coupled plasma (ICP), an upper remote plasma, and a lower remote plasma.

The apparatuses described herein may be used for various etching techniques including, but not limited to, continuous etching methods and cyclic methods such as atomic layer etching.

In accordance with embodiments herein, a method of filling a gap in the features with a silicon-containing material is disclosed. The silicon-containing material with a low dielectric constant (k~3) may be gapfilled in high aspect ratio features without forming voids in the gapfill material. The process disclosed herein can be employed as interconnect process as well as gate metal process.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
depositing a silicon-containing layer in one or more recessed features of a substrate;
exposing at least a portion of the silicon-containing layer to an oxygen-containing species, thereby forming a silicon oxide-containing portion in the silicon-containing layer; and
at least partially etching the silicon oxide-containing portion.

2. The method of claim 1, wherein depositing the silicon-containing layer comprises introducing a silicon-containing precursor to adsorb and thermally decompose on surfaces of the substrate to form the silicon-containing layer.

3. The method of claim 1, wherein the silicon-containing layer comprises silicon carbide, silicon oxycarbide, hydrogenated silicon oxycarbide (SiCOH), or silicon oxycarbonitride.

4. The method of claim 1, wherein the silicon-containing layer comprises a conformal layer.

5. The method of claim 1, wherein the silicon-containing layer comprises a pinched off layer.

6. The method of claim 1, wherein the oxygen-containing species diffuses into the silicon-containing layer to a penetration depth.

7. The method of claim 1, wherein the oxygen-containing species comprises oxygen, ozone, hydrogen peroxide, oxygen-containing radicals, plasmas thereof, or mixtures thereof.

8. The method of claim 1, wherein exposing the at least the portion of the silicon-containing layer comprises converting the portion of the silicon-containing layer to the silicon oxide-containing portion.

9. The method of claim 1, wherein the at least the portion of the silicon-containing layer is exposed to the oxygen-containing species at a pressure of about 0.5 to about 5 Torr.

10. The method of claim 1, wherein the at least the portion of the silicon-containing layer is exposed to the oxygen-containing species at a pressure of about 1 to about 20 Torr.
